(19) United States
(12) Patent Application Publication
(10) Pub. No.: US 2026/0123199 A1
(43) Pub. Date: Apr. 30, 2026

(54) DISPLAY DEVICE

(71) Applicant: LG Display Co., Ltd., Seoul (KR)

(72) Inventors: EunHye LEE, Paju-si (KR); GiSang HONG, Paju-si (KR); Hyeonchul IM, Paju-si (KR)

(73) Assignee: LG Display Co., Ltd., Seoul (KR)

(21) Appl. No.: 19/312,899

(22) Filed: Aug. 28, 2025

(30) Foreign Application Priority Data
Oct. 31, 2024 (KR) 10-2024-0151728

(51) Int. Cl. H10K 59/124; H10K 59/122

(52) U.S. Cl. CPC H10K 59/124; H10K 59/122

(57) ABSTRACT

Discussed are a display device and a display panel. The display device can include a substrate, a first planarization layer disposed on the substrate, conductive patterns positioned on the first planarization layer and spaced apart from each other, a barrier layer disposed on the first planarization layer where at least a portion of a top surface of the conductive patterns is not covered by the barrier layer, and a second planarization layer disposed on the conductive patterns and the barrier layer. In the display device, the planarity of a pixel electrode is improved and outgassing from the planarization layers is reduced or prevented, thereby enabling a low-power display device.

### CROSS-REFERENCE TO RELATED APPLICATION

This application claims priority to Korean Patent Application No. 10-2024-0151728, filed in the Republic of Korea on Oct. 31, 2024, the entire contents of which are hereby expressly incorporated by reference into the present application.

### BACKGROUND

### Field

The present disclosure relates to a display device, more particularly, for example, without limitation, to a display device in which the planarity of a pixel electrode is improved.

### Discussion of the Related Art

As the information society advances, the demand for display devices that display images has increased, and various types of display devices, such as liquid crystal display devices and light-emitting display devices, are being utilized.

A light-emitting display device includes a light-emitting device that emits light in a display area, and the light-emitting device includes an anode, a light-emitting layer, and a cathode. The light-emitting device needs to be formed on a flat surface in order to emit light uniformly and consistently.

Various components including wiring for supplying signals and voltage and a driving element are formed below the light-emitting device. These components can, however, cause surface unevenness and result in height differences.

A planarization layer made of an organic material can be disposed to stably position the light-emitting device on a planarized surface and to planarize a lower portion of the light-emitting device.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventors have recognized the problems and disadvantages of the related art. Accordingly, example embodiments of the present disclosure can provide a display device in which the planarity of a pixel electrode is improved.

Example embodiments of the present disclosure can provide a display device with improved visibility under reflective light.

Example embodiments of the present disclosure can provide a display device with improved gas release from the planarization layers.

The objects of the example embodiments of the present disclosure are not limited to those described above, and other objects not specifically mentioned will be clearly understood by those skilled in the art from the following description.

Example embodiments of the present disclosure can provide a display device including a substrate, a first planarization layer disposed on the substrate, conductive patterns positioned on the first planarization layer, adjacent conductive patterns being spaced apart from each other, a barrier layer disposed on the first planarization layer and at least a portion of top surfaces of the conductive patterns is not covered by the barrier layer, and a second planarization layer disposed on the conductive patterns and the barrier layer, wherein the barrier layer includes a via hole positioned between the conductive patterns.

Example embodiments of the present disclosure can provide a display device including a substrate, a first planarization layer disposed on the substrate, conductive patterns positioned on the first planarization layer and arranged in a first direction, a barrier layer disposed on the first planarization layer, a second planarization layer disposed on the conductive patterns and the barrier layer, a pixel electrode disposed on the second planarization layer, and a bank disposed on the pixel electrode and including an opening that exposes a portion of a top surface of the pixel electrode, wherein the barrier layer includes an open area in which at least a portion of the top surface of the conductive patterns is not covered by the barrier layer, and the open area is positioned to overlap at least a portion of the pixel electrode.

Example embodiments of the present disclosure can provide a display device including a substrate, a first planarization layer disposed on the substrate, conductive patterns positioned on the first planarization layer and extending in a first direction, adjacent conductive patterns being spaced apart in a second direction perpendicular to the first direction, a barrier layer disposed on the conductive patterns and the first planarization layer, a second planarization layer disposed on the conductive patterns and the barrier layer, and a light-emitting area disposed to overlap the conductive patterns, wherein the barrier layer includes an open area in which at least a portion of a top surface of the conductive patterns is not covered, and the open area is positioned to overlap at least a portion of the light-emitting area.

Example embodiments of the present disclosure can provide a display device in which the barrier layer includes a via hole positioned between the conductive patterns, and the first and second planarization layers can be in contact with each other at the via hole.

Example embodiments of the present disclosure can provide a display panel including a substrate, a first planarization layer disposed on the substrate, conductive patterns positioned on the first planarization layer, adjacent conductive patterns being spaced apart from each other, a barrier layer disposed on the first planarization layer and at least a portion of top surfaces of the conductive patterns is not covered by the barrier layer, and a second planarization layer disposed on the conductive patterns and the barrier layer, wherein the barrier layer includes a via hole positioned between the conductive patterns.

Example embodiments of the present disclosure can provide a display panel including a substrate, a first planarization layer disposed on the substrate, conductive patterns positioned on the first planarization layer and arranged in a first direction, a barrier layer disposed on the first planarization layer, a second planarization layer disposed on the conductive patterns and the barrier layer, a pixel electrode disposed on the second planarization layer, and a bank disposed on the pixel electrode and including an opening that exposes a portion of a top surface of the pixel electrode, wherein the barrier layer includes an open area in which at least a portion of the top surface of the conductive patterns is not covered by the barrier layer, and the open area is positioned to overlap at least a portion of the pixel electrode.

Example embodiments of the present disclosure can provide a display panel including a substrate, a first planarization layer disposed on the substrate, conductive patterns positioned on the first planarization layer and extending in a first direction, adjacent conductive patterns being spaced apart in a second direction perpendicular to the first direction, a barrier layer disposed on the conductive patterns and the first planarization layer, a second planarization layer disposed on the conductive patterns and the barrier layer, and a light-emitting area disposed to overlap the conductive patterns, wherein the barrier layer includes an open area in which at least a portion of a top surface of the conductive patterns is not covered, and the open area is positioned to overlap at least a portion of the light-emitting area.

According to example embodiments of the present disclosure, a display device in which the planarity of a pixel electrode is improved can be provided by disposing a barrier layer between conductive patterns located beneath the pixel electrode.

According to example embodiments of the present disclosure, visibility under reflected light can be improved by enhancing the planarity of the pixel electrode.

According to example embodiments of the present disclosure, a display device with improved gas emission from the planarization layers can be provided by disposing a barrier layer with a via hole between the planarization layers.

According to example embodiments of the present disclosure, a low-power display device can be provided by improving both the planarity of the pixel electrode and the outgassing characteristics of the planarization layers.

The effects of the example embodiments described herein are not limited to those listed above, and additional effects not specifically mentioned will be clearly understood by those skilled in the art from the scope of the claims.

### BRIEF DESCRIPTION OF THE DRAWINGS

The present disclosure will be more fully understood from the following detailed description and the accompanying drawings. The detailed description and drawings are provided for illustrative purposes only and are not intended to limit the scope of the present disclosure.

FIG. 1 is a system configuration diagram of a display device according to example embodiments of the present disclosure.

FIG. 2 illustrates a display panel according to example embodiments of the present disclosure.

FIG. 3 is a cross-sectional view of the display panel according to example embodiments of the present disclosure.

FIG. 4 is a plan view schematically illustrating a plurality of sub-pixels disposed in a display area of the display panel according to example embodiments of the present disclosure.

FIG. 5 to FIG. 7 are different example cross-sectional views taken along line A-B of FIG. 4 according to embodiments of the present disclosure.

FIG. 8 and FIG. 9 are different example cross-sectional views taken along line C-D of FIG. 4 according to embodiments of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear.

The shapes, sizes, dimensions (e.g., length, width, height, thickness, radius, diameter, area, etc.), ratios, angles, numbers of elements and the like illustrated in the accompanying drawings for describing the example embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terms such as “include,” “have,” “comprise,” “contain,” “constitute,” “make up of,” “formed of,” and “consist of” used herein are generally intended to allow other components to be added unless the terms are used with the term “only”. As used herein, singular forms are intended to include plural forms unless the context clearly indicates otherwise.

When the position relation between two parts is described using the terms such as “on”, “above”, “over”, “below”, “under”, “beside”, “beneath”, “near”, “close to,” “adjacent to”, “on a side of”, “next”, one or more parts can be positioned between the two parts unless the terms are used with the term “immediately” or “directly”.

Spatially relative terms, such as “under,” “below,” “beneath”, “lower,” “over,” “upper” and the like, can be used herein for ease of description to describe one element or feature's relationship to another element(s) or feature(s) as illustrated in the drawings. It will be understood that the spatially relative terms can encompass different orientations of an element in use or operation in addition to the orientation depicted in the drawings. For example, if an element in the drawings is inverted, elements described as “below” or “beneath” other elements or features would then be oriented “over” the other elements or features. Thus, the example term “below” can encompass both an orientation of below and above. Similarly, the example term “above” or “over” can encompass both an orientation of “above” and “below”.

The word “example” or “exemplary” is used to mean serving as an example or illustration. Aspects are example aspects. The terms such as “embodiments,” “examples,” “aspects,” and the like should not be construed as preferred or advantageous over other implementations. An embodiment, an example, an example embodiment, an aspect, or the like can refer to one or more embodiments, one or more examples, one or more example embodiments, one or more aspects, or the like, unless stated otherwise.

When an element or layer is disposed “on” another element or layer, another layer or another element can be interposed directly on the other element or therebetween.

Terms, such as “first”, “second”, “A”, “B”, “(A)”, or “(B),” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

The term “at least one” should be understood as including all possible combinations which can be suggested from one or more relevant items. For example, the meaning of “at least one of a first item, a second item, or a third item” can be each one of the first item, the second item, or the third item and also be all possible combinations that can be suggested from two or more of the first item, the second item, and the third item.

A term “device” used herein can refer to a display device including a display panel and a driver for driving the display panel. Examples of the display device can include a light emitting element, and the like. In addition, examples of the device can include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning, for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode can be the drain electrode, and the drain electrode can be the source electrode. Further, the source electrode in any one aspect of the present disclosure can be the drain electrode in another aspect of the present disclosure, and the drain electrode in any one aspect of the present disclosure can be the source electrode in another aspect of the present disclosure.

In the specification, in adding reference numerals for elements in each drawing, it should be noted that like reference numerals already used to denote like elements in other drawings are used for elements wherever possible. In addition, the dimension scales of constituent elements shown in the drawings can be different from actual dimension scales, for convenience of description. For example, the dimension scales of constituent elements shown in the drawings should not be interpreted to be the same as those shown in the drawings.

Various example embodiments of the present disclosure will be described in detail with reference to the accompanying drawings. All the components of each display device/apparatus according to all embodiments of the present disclosure are operatively coupled and configured.

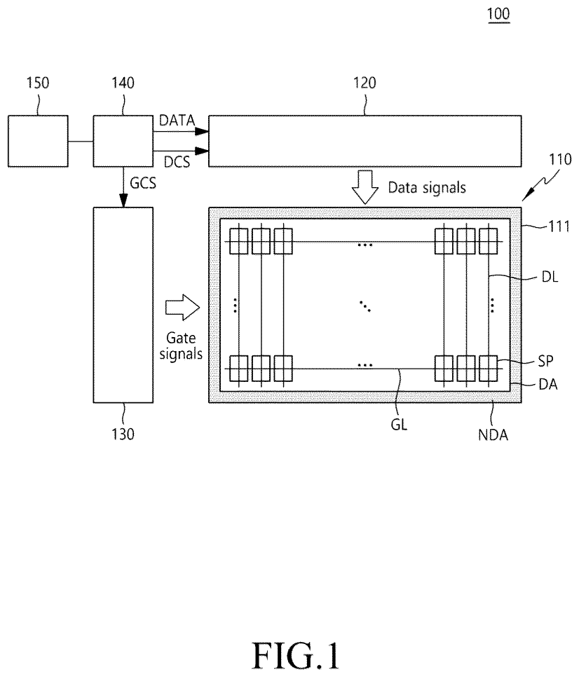

FIG. 1 is a system configuration diagram of a display device 100 according to example embodiments of the present disclosure.

Referring to FIG. 1, the display device 100 according to example embodiments of the present disclosure can include components for image display, such as a display panel 110 and a display driving circuit. The display driving circuit can be a circuit for driving the display panel 110 and can include a data driving circuit 120, a gate driving circuit 130, and a controller 140.

The display panel 110 can include a substrate 111 and a plurality of sub-pixels SP disposed on the substrate 111.

The substrate 111 can include a display area DA (or active area) in which images can be displayed and a non-display area NDA (or non-active area) located outside the display area DA.

The substrate 111 can be made of glass, metal, plastic, or the like, but is not limited thereto. When the display apparatus is a flexible display apparatus, the substrate 101 can be made of a flexible material such as plastic. For example, the substrate can include a flexible polymer film. For example, the flexible polymer film can be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS). For example, the substrate 111 can include a transparent polyimide material, and the present disclosure is not limited thereto.

The display area DA can also be referred to as an active area, and a plurality of sub-pixels SP for image display can be disposed in the display area DA. The non-display area NDA can also be referred to as a non-active area and can include a pad area.

In the display panel 110 according to example embodiments of the present disclosure, the non-display area NDA can be very small. In the present disclosure, the non-display area NDA can also be referred to as a “bezel” or “bezel area.” For example, the non-display area NDA can include a first non-display area located outside the display area DA in a first direction, a second non-display area located outside the display area DA in a second direction, a third non-display area located outside the display area DA in a direction opposite to the first direction, and a fourth non-display area located outside the display area DA in a direction opposite to the second direction.

The first non-display area can include a pad area to which a driving circuit is connected or bonded. The second to fourth non-display areas can be very small in size.

In another example, a boundary region between the display area DA and the non-display area NDA can be bent such that the non-display area NDA is located beneath the display area DA. In this case, when the user views the display device 100 from the front, the non-display area NDA can be barely or not at all visible. For example, the first non-display area can include a bending area. By bending the bending area, the first non-display area may not be visible from the front.

Various types of signal lines for driving the plurality of sub-pixels SP can be disposed on the substrate 111 of the display panel 110.

The display device 100 according to example embodiments of the present disclosure can be a liquid crystal display device or a self-emissive display device in which the display panel 110 emits light by itself. When the display device 100 is a self-emissive display device, each of the plurality of sub-pixels SP can include a light-emitting device.

For example, the display device 100 according to example embodiments of the present disclosure can be an organic light-emitting display device in which the light-emitting device is implemented as an organic light-emitting diode (OLED). In another example, the display device 100 can be an inorganic light-emitting display device in which the light-emitting device is implemented as an inorganic-based light-emitting diode. In yet another example, the display device 100 can be a quantum dot display device in which the light-emitting device is implemented as a quantum dot, which is a semiconductor crystal that emits light by itself.

The unit pixels can be composed of a red (R) sub-pixel, a green (G) sub-pixel, and a blue (B) sub-pixel, or composed of a red (R) sub-pixel, a green (G) sub-pixel, a blue (B) sub-pixel, and a white (W) sub-pixel. However, the present disclosure is not limited thereto and other variations are possible. A plurality of subpixels SP constituting unit pixel can be variously modified in colors and configurations, as necessary.

For example, each of the plurality of subpixels SP can emit light having different wavelengths from each other. For example, the plurality of subpixels SP can include red, green, and blue subpixels, in which the red, green, and blue subpixels can be disposed in a repeated manner. Alternatively, the plurality of subpixels SP can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device disclosures.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

The structure of each sub-pixel SP can vary depending on the type of the display device 100. For example, when the display device 100 is a self-emissive display device in which the sub-pixels SP emit light by themselves, each sub-pixel SP can include a light-emitting device, one or more transistors, and one or more capacitors.

For example, various types of signal lines can include a plurality of data lines DL for delivering data signals (also referred to as data voltages or image signals), and a plurality of gate lines GL for delivering gate signals (also referred to as scan signals).

For example, the plurality of data lines DL and the plurality of gate lines GL can intersect with each other. Each of the plurality of data lines DL can extend and be disposed in a first direction, and each of the plurality of gate lines GL can extend and be disposed in a second direction. The first direction can be a column direction, and the second direction can be a row direction. Alternatively, the first direction can be a row direction, and the second direction can be a column direction. In the following description, for the sake of convenience, the first direction is taken to be the column direction and the second direction is taken to be the row direction. Accordingly, each of the plurality of data lines DL is disposed in the column direction, and each of the plurality of gate lines GL is disposed in the row direction. However, example embodiments of the present disclosure are not limited thereto.

The data driving circuit 120 can be a circuit for driving the plurality of data lines DL and can output data signals to the plurality of data lines DL.

The data driving circuit 120 can receive image data DATA in digital form from the controller 140, convert the received image data DATA into data signals in analog form, and output the data signals to the plurality of data lines DL.

For example, the data driving circuit 120 can be connected to the display panel 110 by a tape automated bonding (TAB) method, connected to a bonding pad of the display panel 110 by a chip-on-glass (COG) method or a chip-on-panel (COP) method, or implemented by a chip-on-film (COF) method to be connected to the display panel 110. However, the connection method is not limited thereto.

The data driving circuit 120 can be connected to one side (for example, an upper side or a lower side) of the display panel 110. Alternatively, depending on the driving method and panel design, the data driving circuit 120 can be connected to both sides (for example, an upper side and a lower side) of the display panel 110, or to two or more of the four sides of the display panel 110.

The data driving circuit 120 can be connected to an outer region of the display area DA of the display panel 110. In another example, the data driving circuit 120 can be disposed in the display area DA of the display panel 110.

The gate driving circuit 130 can be a circuit for driving the plurality of gate lines GL and can output gate signals to the plurality of gate lines GL.

The gate driving circuit 130 can receive, together with gate driving control signals GCS, a first gate voltage corresponding to a turn-on level, and a second gate voltage corresponding to a turn-off level. The gate driving circuit 130 can generate gate signals based on the received signals and supply the generated gate signals to the plurality of gate lines GL.

In the display device 100 according to example embodiments of the present disclosure, the gate driving circuit 130 can be embedded in the display panel 110 as a gate-in-panel (GIP) type. When the gate driving circuit 130 is a gate-in-panel type, it can be formed on the substrate 111 of the display panel 110 during the manufacturing process of the display panel 110.

For example, the gate driving circuit 130 can be disposed in a non-display area NDA of the display panel 110.

In another example, the gate driving circuit 130 can be disposed in the display area DA of the display panel 110. In this case, for example, the gate driving circuit 130 can be disposed in a first sub-area within the display area DA (e.g., a left area or right area within the display area DA). In another example, the gate driving circuit 130 can be disposed in both a first sub-area (e.g., a left or right area within the display area DA) and a second sub-area (e.g., a right area or a left area within the display area DA) within the display area DA.

In the present disclosure, the gate driving circuit 130 embedded in the display panel 110 as a gate-in-panel type can also be referred to as a “gate-in-panel circuit.”

The controller 140 can be configured to be coupled with various processors, for example, a microprocessor, a mobile processor, an application processor, etc. in accordance with a device mounted therein.

The controller 140 can be a device for controlling the data driving circuit 120 and the gate driving circuit 130 and can control the driving timing of the plurality of data lines DL and the plurality of gate lines GL.

The controller 140 can supply a data driving control signal DCS to the data driving circuit 120 to control it and can supply a gate driving control signal GCS to the gate driving circuit 130 to control it.

The controller 140 can receive input image data from a host system 150 and supply image data DATA to the data driving circuit 120 based on the input image data.

The controller 140 can be implemented as a separate component from the data driving circuit 120, or can be integrated with the data driving circuit 120 into a single integrated circuit.

The controller 140 can be a timing controller used in display technology or a control device that includes a timing controller and performs additional control functions. Alternatively, the controller 140 can be a control device different from a timing controller or a circuit within a control device. The controller 140 can be implemented using various types of circuits or electronic components, such as an integrated circuit (IC), a field programmable gate array (FPGA), an application specific integrated circuit (ASIC), or a processor, but is not limited thereto.

The controller 140 can be mounted on a printed circuit board (PCB), a flexible printed circuit (FPC), or the like, and can be electrically connected to the data driving circuit 120 and the gate driving circuit 130 through the PCB, FPC, or the like.

The controller 140 can transmit and receive signals to and from the data driving circuit 120 according to one or more predetermined interfaces. For example, the interface can include a low voltage differential signaling (LVDS) interface, an embedded clock point-to-point interface (EPI), a serial peripheral interface (SPI), or the like, but is not limited thereto.

The display device 100 according to example embodiments of the present disclosure can include a touch sensor and a touch sensing circuit to provide not only an image display function but also a touch sensing function, which detects whether a touch has occurred by a touch object such as a finger or pen, or detects a touch position.

The touch sensing circuit can include a touch driving circuit that drives and senses the touch sensor to generate and output touch sensing data, and a touch controller that detects whether a touch has occurred or detects a touch position based on the touch sensing data.

The touch sensor can include a plurality of touch electrodes. The touch sensor can further include a plurality of touch lines that electrically connect the plurality of touch electrodes to the touch driving circuit.

The touch sensor can be provided outside the display panel 110 in the form of a touch panel or can be located inside the display panel 110. When the touch sensor is located outside the display panel 110 in the form of a touch panel, it is referred to as an external type. When the touch sensor is of the external type, the touch panel and the display panel 110 can be separately manufactured and bonded together during assembly. The external-type touch panel can include a substrate for the touch panel and a plurality of touch electrodes formed on the touch panel substrate.

When the touch sensor is located inside the display panel 110, the touch sensor can be formed on a substrate during the manufacturing process of the display panel 110, together with signal lines and electrodes related to display driving.

The touch driving circuit can supply a touch driving signal to at least one of the plurality of touch electrodes and sense at least one of the plurality of touch electrodes to generate touch sensing data.

The touch sensing circuit can perform touch sensing using a self-capacitance sensing method or a mutual-capacitance sensing method.

When the touch sensing circuit performs touch sensing using the self-capacitance sensing method, the touch sensing circuit can perform touch sensing based on the capacitance between each touch electrode and a touch object (e.g., a finger or pen). In the self-capacitance sensing method, each of the plurality of touch electrodes can serve as both a driving touch electrode and a sensing touch electrode. The touch driving circuit can drive all or some of the plurality of touch electrodes and sense all or some of the plurality of touch electrodes.

When the touch sensing circuit performs touch sensing using the mutual-capacitance sensing method, the touch sensing circuit can perform touch sensing based on the capacitance between the touch electrodes. In the mutual-capacitance sensing method, the plurality of touch electrodes are divided into driving touch electrodes and sensing touch electrodes. The touch driving circuit can drive the driving touch electrodes and sense the sensing touch electrodes.

The touch driving circuit and the touch controller included in the touch sensing circuit can be implemented as separate devices or as a single integrated device. Likewise, the touch driving circuit and the data driving circuit can be implemented as separate devices or as a single device.

The display device 100 can further include a power supply circuit for supplying various power sources to the display driving circuit and/or the touch sensing circuit.

The display device 100 according to example embodiments of the present disclosure can be a mobile terminal such as a smartphone or tablet, or a monitor or television (TV) of various sizes, but is not limited thereto. It can be a display of various types and sizes capable of displaying information or images.

The display device 100 according to example embodiments of the present disclosure can further include electronic devices such as a camera (image sensor) and a detection sensor. For example, the detection sensor can be a sensor that detects an object or a human body by receiving light such as infrared light, ultrasonic waves, or ultraviolet light.

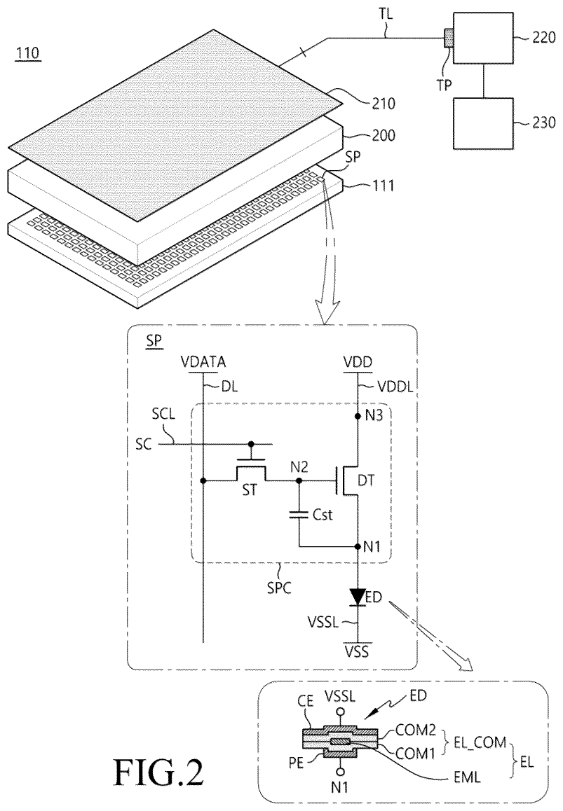

FIG. 2 illustrates a display panel 110 according to example embodiments of the present disclosure. In the following description, content that is the same or similar to what has been described with reference to FIG. 1 will be omitted or briefly described.

Referring to FIG. 2, the display panel 110 can include the substrate 111 on which a plurality of sub-pixels SP are disposed, and an encapsulation layer 200 on the substrate 111. The encapsulation layer 200 can also be referred to as an encapsulation substrate or encapsulating part.

When the display device 100 according to example embodiments of the present disclosure is a self-emissive display device, each of the plurality of sub-pixels SP disposed on the substrate 111 can include a light-emitting device ED (e.g., OLED) and a sub-pixel circuit SPC for driving the light-emitting device ED.

The sub-pixel circuit SPC can include a plurality of transistors and at least one capacitor for driving the light-emitting device ED. In the present disclosure, the sub-pixel circuit SPC can drive the light-emitting device ED by supplying a driving current to the light-emitting device ED at a predetermined timing. The light-emitting device ED can emit light by being driven with the driving current.

The plurality of transistors can include a driving transistor DT for driving the light-emitting device ED and a scan transistor ST that is turned on or off according to a scan signal SC.

Active layers of the transistors can be formed of a semiconductor material, such as an oxide semiconductor, amorphous semiconductor, or polycrystalline semiconductor, but is not limited thereto.

The oxide semiconductor material can have an excellent effect of preventing a leakage current and relatively inexpensive manufacturing cost. The oxide semiconductor can be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor can be made of polycrystalline silicon (poly-Si), but is not limited thereto.

The amorphous semiconductor material can be made of amorphous silicon (a-Si), but is not limited thereto.

The driving transistor DT can supply a driving current to the light-emitting device ED.

The scan transistor ST can be configured to control the electrical state of a corresponding node within the sub-pixel circuit SPC or to control the state or operation of the driving transistor DT.

The at least one capacitor can include a storage capacitor Cst for maintaining a constant voltage during a frame.

To drive the sub-pixel SP, a data signal VDATA, which is an image signal, and a scan signal SC, which is a gate signal, can be applied to the sub-pixel SP. In addition, to drive the sub-pixel SP, a common driving voltage including a first common driving voltage VDD and a second common driving voltage VSS can be applied to the sub-pixel SP.

The light-emitting device ED can include a pixel electrode PE, an intermediate layer EL, and a common electrode CE. The intermediate layer EL can be disposed between the pixel electrode PE and the common electrode CE.

For example, the pixel electrode PE can be an electrode disposed in each sub-pixel SP, and the common electrode CE can be an electrode commonly disposed for a plurality of sub-pixels SP. In one example, the pixel electrode PE can be an anode, and the common electrode CE can be a cathode. In another example, the pixel electrode PE can be a cathode, and the common electrode CE can be an anode. In the following description, for convenience of explanation, an example is given in which the pixel electrode PE is the anode and the common electrode CE is the cathode.

When the light-emitting device ED is an organic light-emitting device, the intermediate layer EL can include an emission layer EML, a first common intermediate layer COM1 between the pixel electrode PE and the emission layer EML, and a second common intermediate layer COM2 between the emission layer EML and the common electrode CE. The first common intermediate layer COM1 and the second common intermediate layer COM2 can collectively be referred to as the common intermediate layer EL_COM.

The emission layer EML can be disposed for each sub-pixel SP, and the common intermediate layer EL_COM can be commonly disposed over a plurality of sub-pixels SP.

The emission layer EML can be disposed for each light-emitting area, and the common intermediate layer EL_COM can be commonly disposed over a plurality of light-emitting areas and non-light-emitting areas.

For example, the first common intermediate layer COM1 can include a hole injection layer HIL and a hole transport layer HTL. The second common intermediate layer COM2 can include an electron transport layer ETL and an electron injection layer EIL.

The hole injection layer can inject holes from the pixel electrode PE into the hole transport layer, and the hole transport layer can transport the holes into the emission layer EML. The electron injection layer can inject electrons from the common electrode CE into the electron transport layer, and the electron transport layer can transport the electrons into the emission layer EML.

For example, the common electrode CE can be electrically connected to the second common driving voltage line VSSL. The second common driving voltage VSS can be applied to the common electrode CE through the second common driving voltage line VSSL. The pixel electrode PE can be electrically connected, either directly or indirectly (through another transistor), to the first node N1 of the driving transistor DT in each sub-pixel SP. In the present disclosure, the “second common driving voltage VSS” can also be referred to as a “base voltage,” and the “second common driving voltage line VSSL” can also be referred to as a “low-potential power supply voltage line” or a “base voltage line.”

Each light-emitting device ED can be formed in an overlapping region of the pixel electrode PE, the emission layer EML within the intermediate layer EL, and the common electrode CE. A light-emitting area can be formed by each light-emitting device ED. For example, the light-emitting area of each light-emitting device ED can include an overlapping region of the pixel electrode PE, the emission layer EML within the intermediate layer EL, and the common electrode CE.

The light-emitting device ED can be an organic light-emitting diode (OLED), an inorganic light-emitting diode (LED), or a quantum dot light-emitting device. For example, when the light-emitting device ED is an OLED, the intermediate layer EL of the light-emitting device ED can include an organic material.

The driving transistor DT can be a transistor for supplying a driving current to the light-emitting device ED. The driving transistor DT can be connected between the first common driving voltage line VDDL and the light-emitting device ED.

The driving transistor DT can include a first node N1, a second node N2, and a third node N3. The first node N1 can be electrically connected to the light-emitting device ED. The second node N2 can be a node to which a data signal VDATA is applied. The third node N3 can be a node to which the first common driving voltage VDD is applied from the first common driving voltage line VDDL.

In the driving transistor DT, the second node N2 can serve as a gate node, the first node N1 can serve as a source node or a drain node, and the third node N3 can serve as a drain node or a source node. In the following description, for convenience of explanation, an example is given in which the second node N2 serves as a gate node (or gate electrode), the first node N1 serves as a source node (or source electrode), and the third node N3 serves as a drain node (or drain electrode), but example embodiments of the present disclosure are not limited thereto.

The scan transistor ST included in the sub-pixel circuit SPC illustrated in FIG. 2 can be a switching transistor for delivering the data signal VDATA, which is an image signal, to the second node N2, which is the gate node of the driving transistor DT.

The scan transistor ST can be controlled to turn on or off by a scan signal SC, which is a gate signal applied through a scan line SCL, which is one type of gate line GL, thereby controlling the electrical connection between the second node N2 of the driving transistor DT and the data line DL. A drain electrode or source electrode of the scan transistor ST can be electrically connected to the data line DL. A source electrode or drain electrode of the scan transistor ST can be electrically connected to the second node N2 of the driving transistor DT. A gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1, and a second capacitor electrode electrically connected to the second node N2 of the driving transistor DT or corresponding to the second node N2.

The storage capacitor Cst can be an external capacitor designed outside the driving transistor DT, rather than an internal parasitic capacitor (e.g., Cgs or Cgd) that can exist between the first node N1 and the second node N2 of the driving transistor DT.

Each of the driving transistor DT and the scan transistor ST can be an n-type transistor or a p-type transistor.

The display panel 110 can have a top-emission structure or a bottom-emission structure.

When the display panel 110 has a top-emission structure, at least a portion of the sub-pixel circuit SPC can overlap with at least a portion of the light-emitting device ED in the vertical direction. Accordingly, the area of the light-emitting region can be increased and the aperture ratio can be improved.

When the display panel 110 has a bottom-emission structure, the sub-pixel circuit SPC may not overlap with the light-emitting device ED in the vertical direction.

The sub-pixel circuit SPC can have a 2T1C structure including two transistors (DT and ST) and one capacitor (Cst). In some cases, the sub-pixel circuit SPC can further include one or more additional transistors or one or more additional capacitors.

For example, the sub-pixel circuit SPC can have an 8T1C structure including eight transistors and one capacitor. In another example, the sub-pixel circuit SPC can have a 6T2C structure including six transistors and two capacitors. In yet another example, the sub-pixel circuit SPC can have a 7T1C structure including seven transistors and one capacitor. However, example embodiments of the present disclosure are not limited thereto.

Depending on the structure of the sub-pixel circuit SPC, the types and number of gate lines supplying gate signals to the sub-pixel SP can vary. In addition, depending on the structure of the sub-pixel circuit SPC, the types and number of common driving voltages supplied to the sub-pixel SP can also vary.

The circuit elements included in each sub-pixel SP (for example, a light-emitting device ED implemented as an organic light-emitting diode (OLED) containing organic material) are vulnerable to external moisture and oxygen. Accordingly, the encapsulation layer 200 can be disposed in the display panel 110 to prevent such external moisture or oxygen from penetrating into the circuit elements, such as the light-emitting device ED.

The encapsulation layer 200 can be configured in various forms to prevent the light-emitting devices ED from being exposed to moisture or oxygen. For example, the encapsulation layer 200 can include two or more layers in which organic layers and inorganic layers are alternately stacked. However, example embodiments of the present disclosure are not limited thereto.

For example, the encapsulation layer 200 has a structure in which inorganic encapsulation layers and organic encapsulation layers are alternately stacked, such that the encapsulation layer 200 can protect the light-emitting element while inhibiting moisture or oxygen from penetrating into the light-emitting element. For example, the encapsulation layer 200 can have a multi-insulating film structure in which organic films and inorganic films are stacked alternately. The inorganic film can block permeation of moisture or oxygen. The organic film can planarize a surface of the inorganic film. When the organic film and the inorganic film are stacked in multiple layers, a movement path of moisture or oxygen can be longer than that of a single layer, thereby effectively blocking the permeation of moisture and oxygen affecting the light emitting layer. The encapsulation layer 200 can be formed by sequentially stacking a first inorganic encapsulation layer, a first organic encapsulation layer, and a second inorganic encapsulation layer. The encapsulation layer 200 can further include one or more organic encapsulation layers and/or at least one inorganic encapsulation layer.

The display device 100 according to example embodiments of the present disclosure can include a touch sensor layer 210 for sensing a user's touch, which includes a plurality of sensor electrodes, a touch driving circuit 220 for sensing the plurality of sensor electrodes, and a touch controller 230 for determining whether a touch has occurred or to determine the touch coordinates based on sensing results (touch sensing data) from the touch driving circuit 220.

The touch sensor layer 210 can be embedded in the display panel 110. For example, the touch sensor layer 210 can be disposed on the encapsulation layer 200 in the display panel 110.

The display panel 110 can further include a plurality of touch pads TP electrically connected to the touch driving circuit 220, and a plurality of touch lines TL for electrically connecting the plurality of sensor electrodes in the touch sensor layer 210 to the plurality of touch pads TP connected to the touch driving circuit 220.

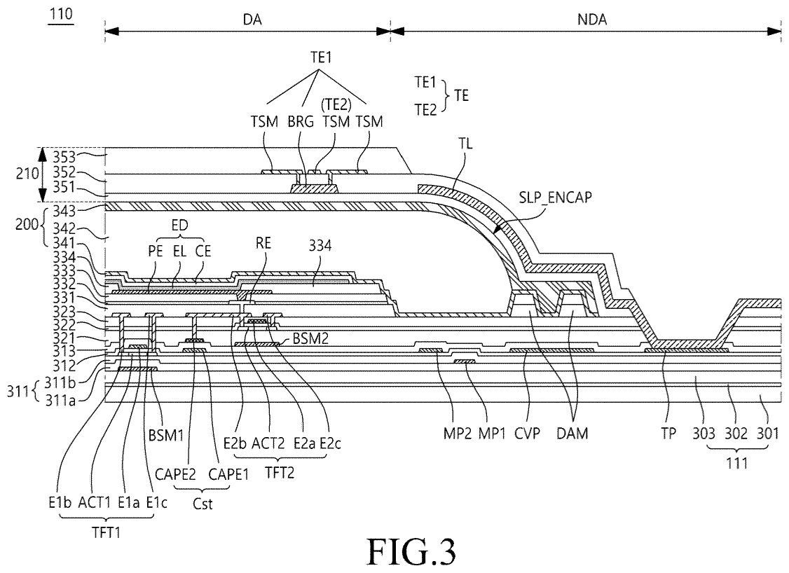

FIG. 3 is a cross-sectional view of a display panel 110 according to example embodiments of the present disclosure. In the following description, details that are the same or similar to those described with reference to FIG. 1 and FIG. 2 will be omitted or briefly described.

Referring to FIG. 3, the display panel 110 according to example embodiments of the present disclosure can include, in terms of a vertical structure, a transistor formation portion, a light-emitting device formation portion, and an encapsulation portion.

The substrate 111 can be a single-layer or multilayer substrate and can be made of glass or plastic. When the substrate 111 is a multilayer structure, it can include a first substrate 301, a substrate intermediate layer 302, and a second substrate 303. The substrate intermediate layer 302 can be located between the first substrate 301 and the second substrate 303. For example, each of the first substrate 301 and the second substrate 303 can be a polyimide (PI) layer. The substrate intermediate layer 302 can be an inorganic insulating layer. When charge is accumulated in the first substrate 301, which is a polyimide layer, the substrate intermediate layer 302 can block the charge from affecting the transistors formed on the second substrate 303, which is also a polyimide layer.

The substrate intermediate layer 302 can also prevent moisture from penetrating upward through the first substrate 301. For example, the substrate intermediate layer 302 can be formed of a single layer or a multilayer structure of silicon nitride (SiNx) or silicon oxide (SiOx), or a dual-layer structure of silicon oxide (SiOx) and silicon nitride (SiNx). For example, the substrate intermediate layer 302 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto. However, the substrate intermediate layer 302 can be excluded in accordance with the structure or properties of the display device. However, example embodiments of the present disclosure are not limited thereto.

The transistor formation portion can include the substrate 111, various insulating layers 311, 312, 313, 321, 322, and 323 on the substrate 111, various transistors TFT1, and TFT2, a storage capacitor Cst, and various electrodes or signal wirings.

The transistors TFT1 and TFT2 included in the transistor formation portion can include a first transistor TFT1 and a second transistor TFT2.

The first transistor TFT1 can include a first active layer ACT1, a first electrode E1a, a second electrode E1b, and a third electrode E1c. The first active layer ACT1 can be a first semiconductor layer, but example embodiments of the present disclosure are not limited thereto. For example, the first active layer ACT1 can be formed of an oxide semiconductor, amorphous silicon, polysilicon, or low-temperature polysilicon (LTPS), but is not limited thereto. The first transistor TFT1 can be implemented as a p-channel transistor or an n-channel transistor.

The first electrode E1a can be a gate electrode, the second electrode E1b can be a source electrode or a drain electrode, and the third electrode E1c can be a drain electrode or a source electrode. In the following description, for convenience of explanation, the first electrode E1a is referred to as the first gate electrode, the second electrode E1b as the first source electrode, and the third electrode E1c as the first drain electrode. However, example embodiments of the present disclosure are not limited thereto.

The second transistor TFT2 can include a second active layer ACT2, a fourth electrode E2a, a fifth electrode E2b, and a sixth electrode E2c. The second active layer ACT2 can be a second semiconductor layer, but is not limited thereto. For example, the second active layer ACT2 can be formed of an oxide semiconductor, amorphous silicon, polysilicon, or low-temperature polysilicon (LTPS), but example embodiments of the present disclosure are not limited thereto. The second transistor TFT2 can be implemented as a p-channel transistor or an n-channel transistor.

For example, one of the first transistor TFT1 and the second transistor TFT2 can include an oxide semiconductor as the active layer. In another example, one of the first transistor TFT1 and the second transistor TFT2 can include low-temperature polysilicon as the active layer. In another example, both the first transistor TFT1 and the second transistor TFT2 can include an oxide semiconductor as the active layer. In another example, both the first transistor TFT1 and the second transistor TFT2 can include low-temperature polysilicon as the active layer. In yet another example, the driving transistor DT among the first transistor TFT1 and the second transistor TFT2 can include an oxide semiconductor as the active layer, and the scan transistor ST can include low-temperature polysilicon as the active layer. In yet another example, the driving transistor DT can include low-temperature polysilicon as the active layer, and the scan transistor ST can include an oxide semiconductor as the active layer. In another example, a transistor included in the gate-in-panel (GIP) type gate driving circuit 130 can include an oxide semiconductor or low-temperature polysilicon as the active layer. In yet another example, all transistors formed on the substrate 111 and the transistors included in the GIP-type gate driving circuit 130 can include oxide semiconductors as the active layer.

The fourth electrode E2a can be a gate electrode, the fifth electrode E2b can be a source electrode or a drain electrode, and the sixth electrode E2c can be a drain electrode or a source electrode. In the following description, for convenience of explanation, the fourth electrode E2a is referred to as the second gate electrode, the fifth electrode E2b as the second source electrode, and the sixth electrode E2c as the second drain electrode. However, example embodiments of the present disclosure are not limited thereto.

The second active layer ACT2 of the second transistor TFT2 can be located higher from the substrate 111 than the first active layer ACT1 of the first transistor TFT1.

A first buffer layer 311 can be disposed below the first active layer ACT1 of the first transistor TFT1, and a second buffer layer 321 can be disposed below the second active layer ACT2 of the second transistor TFT2. For example, the first active layer ACT1 of the first transistor TFT1 can be located on the first buffer layer 311, and the second active layer ACT2 of the second transistor TFT2 can be located on the second buffer layer 321. The second buffer layer 321 can be positioned higher than the first buffer layer 311.

The storage capacitor Cst can be disposed in various metal layers within the display panel 110. For example, the storage capacitor Cst can include a first capacitor electrode CAPE1 and a second capacitor electrode CAPE2.

The light-emitting device formation portion can include a plurality of light-emitting devices ED disposed on at least one planarization layer 331 or 333. Each of the plurality of light-emitting devices ED can include a pixel electrode PE, an intermediate layer EL, and a common electrode CE.

The encapsulation portion can include the encapsulation layer 200 on the plurality of light-emitting devices ED. The encapsulation layer 200 can be a single layer or multiple layers. In addition to the encapsulation layer 200, the encapsulation portion can further include a dam (DAM).

Hereinafter, the vertical structure of the display panel 110 according to example embodiments of the present disclosure will be described in more detail with reference to FIG. 3.

Referring to FIG. 3, the first buffer layer 311 can be disposed on the substrate 111. The first buffer layer 311 can be a single layer or multiple layers. When the first buffer layer 311 is a multilayer structure, it can include a multi-buffer layer 311a and an active buffer layer 311b.

The multi-buffer layer 311a can be an inorganic insulating layer. The multi-buffer layer 311a can block or delay the diffusion of moisture or oxygen that has penetrated the substrate 111. For example, the multi-buffer layer 311a can be formed of a single layer or a multilayer structure of silicon nitride (SiNx), silicon oxide (SiOx), or silicon oxynitride (SiOxNy), but is not limited thereto. For example, the multi-buffer layer 311a can be formed as a single layer of any one of a silicon oxide (SiOx) film, a silicon nitride (SiNx) film, and a silicon oxynitride (SiOxNx) film, or a multilayer thereof. For example, the multi-buffer layer 311a can be formed by inorganic film in a single layer or in multiple layers, for example, the inorganic film in a single layer can be a silicon oxide (SiOx) film, a silicon nitride (SiNx) film or silicon oxynitride (SiOxNx) film, and inorganic films in multiple layers can formed by alternately stacking at least one of one or more silicon oxide (SiOx) films, one or more silicon nitride (SiNx) films and one or more silicon oxynitride (SiOxNx) films, and one or more amorphous silicon (a-Si), but the present disclosure is not limited thereto.

The active buffer layer 311b can be an inorganic insulating layer. The active buffer layer 311b can protect the first active layer ACT1 and can serve to block or delay various types of defects entering from the substrate 111. For example, the active buffer layer 311b can be formed of a single layer or a multilayer structure of amorphous silicon (a-Si), silicon nitride (SiNx), or silicon oxide (SiOx), but is not limited thereto.

The first active layer ACT1 of the first transistor TFT1 can be disposed on the first buffer layer 311. The first active layer ACT1 can include a channel region in which a channel is formed, a source connection region on one side of the channel region, and a drain connection region on the other side of the channel region.

A first gate insulating layer 312 can be disposed on the first active layer ACT1 of the first transistor TFT1. The first gate insulating layer 312 can be formed of a single layer or a multilayer structure of silicon nitride (SiNx) or silicon oxide (SiOx), but is not limited thereto. For example, the first gate insulating layer 312 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto. A first gate electrode E1a of the first transistor TFT1 can be disposed on the first gate insulating layer 312.

A first interlayer insulating layer 313 can be disposed on the first gate electrode E1a of the first transistor TFT1. The first interlayer insulating layer 313 can be formed of a single layer or a multilayer structure of silicon nitride (SiNx) or silicon oxide (SiOx), but is not limited thereto. For example, the first interlayer insulating layer 313 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto.

A second buffer layer 321 can be disposed on the first interlayer insulating layer 313. The second buffer layer 321 can be formed of a single layer or a multilayer structure of silicon nitride (SiNx) or silicon oxide (SiOx), but is not limited thereto. For example, the second buffer layer 321 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto.

A second active layer ACT2 of the second transistor TFT2 can be disposed on the second buffer layer 321. The second active layer ACT2 can include a channel region in which a channel is formed, a source connection region on one side of the channel region, and a drain connection region on the other side of the channel region.

A second gate insulating layer 322 can be disposed on the second active layer ACT2 of the second transistor TFT2. The second gate insulating layer 322 can be formed of a single layer or a multilayer structure of silicon nitride (SiNx) or silicon oxide (SiOx), but is not limited thereto. For example, the second gate insulating layer 322 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto. A second gate electrode E2a of the second transistor TFT2 can be disposed on the second gate insulating layer 322.

A second interlayer insulating layer 323 can be disposed on the second gate electrode E2a of the second transistor TFT2. The second interlayer insulating layer 323 can be formed of a single layer or a multilayer structure of silicon nitride (SiNx) or silicon oxide (SiOx), but is not limited thereto. For example, the second interlayer insulating layer 323 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto.

The first source electrode E1b and the first drain electrode E1c of the first transistor TFT1 and the second source electrode E2b and the second drain electrode E2c of the second transistor TFT2 can be disposed on the second interlayer insulating layer 323.

The first source electrode E1b and the first drain electrode E1c of the first transistor TFT1 can be connected to the source connection region and the drain connection region of the first active layer ACT1 through contact holes in the second interlayer insulating layer 323, the second gate insulating layer 322, the second buffer layer 321, the first interlayer insulating layer 313, and the first gate insulating layer 312.

The second source electrode E2b and the second drain electrode E2c of the second transistor TFT2 can be connected to the source connection region and the drain connection region of the second active layer ACT2 through contact holes in the second interlayer insulating layer 323 and the second gate insulating layer 322.

The first source electrode E1b and the first drain electrode E1c of the first transistor TFT1, and the second source electrode E2b and the second drain electrode E2c of the second transistor TFT2 can include a first metal and can be disposed in a first metal layer. Here, the first metal and the first metal layer can be referred to as a first source-drain metal and a first source-drain metal layer, respectively.

For example, the storage capacitor Cst can be formed by the first capacitor electrode CAPE1 and the second capacitor electrode CAPE2. In some cases, the storage capacitor Cst can be formed by three or more capacitor electrodes, or can be formed in a configuration in which two or more capacitors are connected in parallel.

Each of the first capacitor electrode CAPE1 and the second capacitor electrode CAPE2 can be disposed in various metal layers within the display panel 110.

For example, the first capacitor electrode CAPE1 can include the same first gate metal as the first gate electrode E1a of the first transistor TFT1 formed on the first gate insulating layer 312 and can be disposed in a first gate metal layer.

For example, the second capacitor electrode CAPE2 can be disposed on the first interlayer insulating layer 313.

The second source electrode E2b of the second transistor TFT2 can be electrically connected to the second capacitor electrode CAPE2 through the contact holes in the second interlayer insulating layer 323, the second gate insulating layer 322, and the second buffer layer 321.

For example, the first transistor TFT1 can correspond to the scan transistor ST of FIG. 2, and the second transistor TFT2 can correspond to the driving transistor DT of FIG. 2.

The transistor formation portion can further include various metal patterns MP1 and MP2. For example, the first metal pattern MP1 can be disposed between the multi-buffer layer 311a and the active buffer layer 311b included in the first buffer layer 311. The second metal pattern MP2 can include the same first gate metal as the first gate electrode E1a of the first transistor TFT1 and can be disposed in the first gate metal layer. However, example embodiments of the present disclosure are not limited thereto.

Each of the first metal pattern MP1 and the second metal pattern MP2 can be disposed in the display area DA or the non-display area NDA.

The transistor formation portion can further include a first shield metal BSM1 that is disposed on the substrate 111, overlaps with the first active layer ACT1 of the first transistor TFT1, and is positioned below the first active layer ACT1 of the first transistor TFT1. For example, the first shield metal BSM1 can be disposed between the substrate 111 and the first buffer layer 311, or between the multi-buffer layer 311a and the active buffer layer 311b.

The transistor formation portion can further include a second shield metal BSM2 that is disposed on the substrate 111, overlaps with the second active layer ACT2 of the second transistor TFT2, and is positioned below the second active layer ACT2 of the second transistor TFT2.

For example, the second shield metal BSM2 can be disposed in a metal layer between the first interlayer insulating layer 313 and the second buffer layer 321. The second shield metal BSM2 can be disposed in the same metal layer as the second capacitor electrode CAPE2.

In another example, the second shield metal BSM2 can be disposed in the same first gate metal layer as the first gate electrode E1a of the first transistor TFT1. The transistor formation portion can further include a common driving voltage pattern CVP to which a common driving voltage is applied. For example, the common driving voltage applied to the common driving voltage pattern CVP can be referred to as a power supply signal, and can be a first common driving voltage VDD or a second common driving voltage VSS. The first common driving voltage VDD can also be referred to as a high-potential power supply voltage (high-potential power signal), and the second common driving voltage VSS can also be referred to as a low-potential power supply voltage (low-potential power signal) or a base voltage.

The common driving voltage pattern CVP can be disposed in the display area DA or the non-display area NDA.

At least one planarization layer can be disposed on the first transistor TFT1 and the second transistor TFT2. The example shown in FIG. 3 illustrates a case where two planarization layers 331 and 333 are disposed on the first transistor TFT1 and the second transistor TFT2. In some cases, three or more planarization layers can be disposed thereon; however, example embodiments of the present disclosure are not limited thereto. The planarization layer can be an organic insulating layer capable of performing a planarization function.

The first planarization layer 331 can be disposed on the first source electrode E1b and the first drain electrode E1c of the first transistor TFT1, and on the second source electrode E2b and the second drain electrode E2c of the second transistor TFT2. The first planarization layer 331 can be disposed to cover both the first transistor TFT1 and the second transistor TFT2. The first planarization layer 331 can be an organic insulating layer that planarizes and protects the upper portions of the first transistor TFT1 and the second transistor TFT2. For example, the first planarization layer 331 can be formed of an organic insulating material such as acryl resin, epoxy resin, phenolic resin, polyamide resin, or polyimide resin.

Various conductive patterns can be disposed on the first planarization layer 331. The conductive patterns can include a first conductive pattern, a second conductive pattern, and a third conductive pattern. The conductive patterns can be formed using a metal, alloy, metal nitride, conductive metal oxide, or a transparent conductive material.

A relay electrode RE can be disposed on the first planarization layer 331. The relay electrode RE can correspond to the third conductive pattern. The relay electrode RE can be electrically connected to the second source electrode E2b of the second transistor TFT2 through a contact hole of the first planarization layer 331. Here, the second source electrode E2b of the second transistor TFT2 can be electrically connected to the second capacitor electrode CAPE2 of the storage capacitor Cst.

The relay electrode RE can be disposed in a second metal layer on the first planarization layer 331 and can include a second metal. The second metal and the second metal layer can be referred to as a second source-drain metal and a second source-drain metal layer, respectively.

A barrier layer 332 can be disposed on the first planarization layer 331. The barrier layer 332 can be disposed so as to expose the top surface of the relay electrode RE. The barrier layer 332 can compensate for step differences formed by various components such as signal wirings, voltage wirings, and driving elements. The barrier layer 332 can include an inorganic insulating material. For example, the barrier layer 332 can be formed of silicon nitride (SiNx), silicon oxide (SiOx), silicon oxynitride (SiOxNy), or aluminum oxide (AlOx), but is not limited thereto.

A second planarization layer 333 can be disposed on the barrier layer 332 and the relay electrode RE. For example, the second planarization layer 333 can be formed of an organic insulating material such as acryl resin, epoxy resin, phenolic resin, polyamide resin, or polyimide resin.

The light-emitting device formation portion can be disposed on the second planarization layer 333. The light-emitting device ED can be formed on the second planarization layer 333 and can include a pixel electrode PE, an intermediate layer EL, and a common electrode CE. A light-emitting area of the light-emitting device ED can be formed in a region where the pixel electrode PE, the intermediate layer EL, and the common electrode CE overlap and make contact with each other.

The pixel electrode PE can be disposed on the second planarization layer 333. The pixel electrode PE can be electrically connected to the relay electrode RE through a contact hole of the second planarization layer 333.

A bank 334 can be disposed on the pixel electrode PE. An opening of the bank 334 can expose a portion of the pixel electrode PE to form a light-emitting area. For example, the opening of the bank 334 can overlap a portion of the pixel electrode PE. The bank 334 can be formed of an inorganic insulating material such as silicon nitride (SiNx) or silicon oxide (SiOx), or an organic insulating material such as benzocyclobutene-based resin, acryl-based resin, or imide-based resin, but is not limited thereto. A spacer can further be disposed on the bank 334.

Meanwhile, the bank can include a first bank and a second bank. The first bank can be made of an opaque material (e.g., black material) to suppress the optical interference between adjacent sub-pixels. The second bank can be made of a transparent material. The first bank and the second bank can include, but is not limited to, a light-shielding material made of at least one of a color pigment, an organic black material, and carbon.

The first bank and the second bank can be formed as separate configurations, but can also be formed integrally to form one bank. For example, the first bank and the second bank can be integrated as one bank and implemented.

The first bank and the second bank can be disposed at a boundary between the plurality of subpixels SP and suppress a color mixture of light beams from the plurality of subpixels SP.

The intermediate layer EL of the light-emitting device ED can be disposed on a portion of the pixel electrode PE and on the bank 334. The common electrode CE can be disposed on the intermediate layer EL.

The encapsulation portion can be disposed on the light-emitting device formation portion and can be located on the common electrode CE. The encapsulation portion can include the encapsulation layer 200 formed on the common electrode CE.

The encapsulation layer 200 can prevent moisture or oxygen from penetrating into the light-emitting device ED. For example, the encapsulation layer 200 can prevent moisture or oxygen from penetrating into the organic material contained in the intermediate layer EL of the light-emitting device ED. The encapsulation layer 200 can be a single layer or a multilayer structure; however, example embodiments of the present disclosure are not limited thereto.

For example, the encapsulation layer 200 can include a first encapsulation layer 341, a second encapsulation layer 342, and a third encapsulation layer 343. The first encapsulation layer 341 and the third encapsulation layer 343 can include inorganic layers, and the second encapsulation layer 342 can include an organic layer.

The first encapsulation layer 341 can be disposed on the common electrode CE and can be positioned closest to the light-emitting device ED. The first encapsulation layer 341 can be formed of an inorganic insulating material that allows for low-temperature deposition. For example, the first encapsulation layer 341 can be formed of silicon nitride (SiNx), silicon oxide (SiOx), silicon oxynitride (SiOxNy), or aluminum oxide (AlOx). Since the first encapsulation layer 341 is deposited under a low-temperature condition, it can prevent damage to the intermediate layer EL containing organic material during the deposition process.

The second encapsulation layer 342 can be formed with a smaller area than the first encapsulation layer 341. In this case, the second encapsulation layer 342 can be formed to expose both end portions of the first encapsulation layer 341. The second encapsulation layer 342 can serve as a buffer to relieve stress between layers caused by bending of the display device and can enhance the planarization performance. For example, the second encapsulation layer 342 can be formed of an organic insulating material such as acryl resin, epoxy resin, polyimide, polyethylene, or silicon oxycarbon (SiOC). For example, the second encapsulation layer 342 can be formed by an inkjet process, but is not limited thereto.

The third encapsulation layer 343 can be formed on the upper side of the substrate 111 on which the second encapsulation layer 342 is formed, and can cover the upper and side surfaces of each of the second encapsulation layer 342 and the first encapsulation layer 341. In this case, the third encapsulation layer 343 can minimize or block moisture or oxygen from penetrating into the first encapsulation layer 341 and the second encapsulation layer 342. For example, the third encapsulation layer 343 can be formed of an inorganic insulating material such as silicon nitride (SiNx), silicon oxide (SiOx), silicon oxynitride (SiOxNy), or aluminum oxide (AlOx), but is not limited thereto.

The display panel 110 according to example embodiments of the present disclosure can include an embedded touch sensor. In this case, the display panel 110 can include a touch sensor layer 210 formed on the encapsulation layer 200.

The touch sensor layer 210 can include a plurality of touch electrodes TE, and can further include sensor metal TSM and bridge metal BRG to form the plurality of touch electrodes TE. In the example embodiments of the present disclosure, the sensor metal TSM can also be referred to as the sensor metal layer TSM, and the bridge metal BRG can also be referred to as the bridge metal layer BRG.

The touch sensor layer 210 can further include insulating layers such as a sensor buffer layer 351 disposed on the encapsulation layer 200, a sensor interlayer insulating layer 352 disposed on the sensor buffer layer 351, and a sensor passivation layer 353 disposed on the sensor interlayer insulating layer 352. Here, the sensor buffer layer 351 can be omitted.

The bridge metal BRG can be disposed between the sensor buffer layer 351 and the sensor interlayer insulating layer 352, and the sensor metal TSM can be disposed between the sensor interlayer insulating layer 352 and the sensor passivation layer 353.

The sensor buffer layer 351 can be disposed on the encapsulation layer 200. The sensor buffer layer 351 can prevent damage to the encapsulation layer 200 and can serve to block interference signals from the transistors TFT1 and TFT2 from affecting the touch electrodes TE. The sensor buffer layer 351 can facilitate formation of the touch electrodes TE on the encapsulation layer 200 and can improve the adhesion between the touch electrodes TE and the encapsulation layer 200. The sensor buffer layer 351 can be an inorganic insulating layer. For example, the sensor buffer layer 351 can include an inorganic insulating material such as silicon oxide (SiOx), silicon nitride (SiNx), or silicon oxynitride (SiOxNy), and can be a single layer or multilayer structure, but is not limited thereto. For example, the sensor buffer layer 351 can be formed as a single layer of any one of a silicon oxide (SiOx) film, a silicon nitride (SiNx) film, and a silicon oxynitride (SiOxNx) film, or a multilayer thereof. For example, the sensor buffer layer 351 can be formed by inorganic film in a single layer or in multiple layers, for example, the inorganic film in a single layer can be a silicon oxide (SiOx) film, a silicon nitride (SiNx) film or silicon oxynitride (SiOxNx) film, and inorganic films in multiple layers can formed by alternately stacking at least one of one or more silicon oxide (SiOx) films, one or more silicon nitride (SiNx) films and one or more silicon oxynitride (SiOxNx) films, and one or more amorphous silicon (a-Si), but the present disclosure is not limited thereto.

The sensor buffer layer 351 can be disposed on the encapsulation layer 200. The sensor buffer layer 351 can facilitate formation of the touch electrodes TE on the encapsulation layer 200 and can enhance the adhesion of the touch electrodes TE on the encapsulation layer 200. The sensor buffer layer 351 can also be an organic insulating layer. For example, the sensor buffer layer 351 can be formed of an organic insulating material such as acryl-based, epoxy-based, or siloxane-based resin, but is not limited thereto.

Each of the plurality of touch electrodes TE can be formed of the sensor metal TSM. Each of the plurality of touch electrodes TE can be a mesh-type electrode having a plurality of openings.

The plurality of touch electrodes TE can include a first touch electrode TE1 and a second touch electrode TE2. The sensor metal TSM included in the first touch electrode TE1 can be electrically connected via the bridge metal BRG. For example, sensor metals TSM that are spaced apart from each other can be electrically connected by the bridge metal BRG to form a single first touch electrode TE1.

The bridge metal BRG can be disposed on the sensor buffer layer 351, and the sensor interlayer insulating layer 352 can be disposed on the bridge metal BRG. The sensor interlayer insulating layer 352 can be an inorganic insulating layer. For example, the sensor interlayer insulating layer 352 can be formed of silicon nitride (SiNx), silicon oxide (SiOx), silicon oxynitride (SiOxNy), titanium oxide (TiOx), or aluminum oxide (AlOx), but is not limited thereto. For example, the sensor interlayer insulating layer 352 can be formed as a single layer of any one of a silicon oxide (SiOx) film, a silicon nitride (SiNx) film, and a silicon oxynitride (SiOxNx) film, or a multilayer thereof. For example, the sensor interlayer insulating layer 352 can be formed by inorganic film in a single layer or in multiple layers, for example, the inorganic film in a single layer can be a silicon oxide (SiOx) film, a silicon nitride (SiNx) film or silicon oxynitride (SiOxNx) film, and inorganic films in multiple layers can formed by alternately stacking at least one of one or more silicon oxide (SiOx) films, one or more silicon nitride (SiNx) films and one or more silicon oxynitride (SiOxNx) films, and one or more amorphous silicon (a-Si), but the present disclosure is not limited thereto.

The sensor metal TSM can be disposed on the sensor interlayer insulating layer 352. A portion of the sensor metal TSM can be connected to the corresponding bridge metal BRG through a contact hole of the sensor interlayer insulating layer 352.

The sensor metal TSM and the bridge metal BRG can be disposed so as not to overlap with the light-emitting device ED. The sensor metal TSM and the bridge metal BRG can overlap the bank 334.

A plurality of sensor metals TSM can form a single touch electrode TE, and can be disposed in a mesh pattern and electrically connected. One portion of the sensor metal TSM and another portion of the sensor metal TSM can be electrically connected through the bridge metal BRG to form a single touch electrode TE.

A sensor passivation layer 353 can be disposed to cover the sensor metal TSM and the bridge metal BRG. The sensor passivation layer 353 can be an organic insulating layer. Such an organic insulating layer can be formed of the same material as the aforementioned planarization layers 331 and 333, for example. The organic insulating layer can be formed of a different material than the second encapsulation layer 342. For example, the sensor passivation layer 353 can be formed of a photo-curable organic material selected from acryl-based, polyimide-based, or siloxane-based resins, but is not limited thereto.

A touch line TL can electrically connect the touch electrode TE and a touch pad TP. The touch line TL can be formed of at least one of the sensor metal TSM and the bridge metal BRG.

When the display panel 110 includes a built-in touch sensor, the touch line TL can extend along an inclined outer surface SLP_ENCAP of the encapsulation layer 200 and can extend over a dam (DAM) to the touch pad TP located in the non-display area NDA.

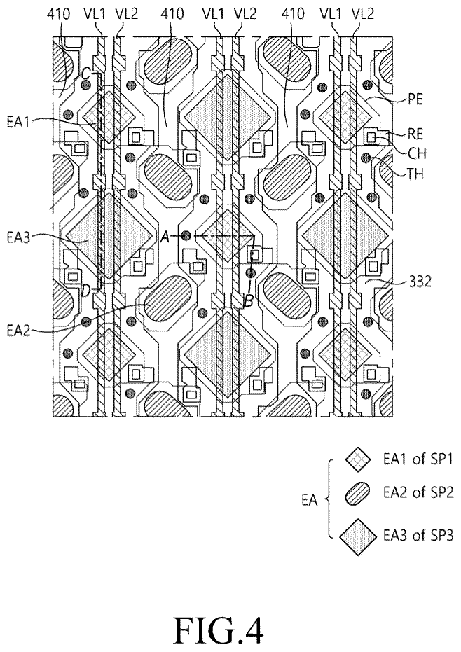

FIG. 4 is a plan view schematically illustrating a plurality of subpixels SP disposed in the display area DA of the display panel 110 according to example embodiments of the present disclosure. In the following description, the same or similar descriptions as those provided with reference to FIG. 1 to FIG. 3 are omitted or briefly explained.

In FIG. 4, among the various components described in FIG. 3, the light-emitting areas EA, conductive patterns VL1, VL2, 410, and RE, the barrier layer 332, and the pixel electrode PE are illustrated. The light-emitting area EA can correspond to the opening portion of the aforementioned bank 334.

Referring to FIG. 4, the plurality of subpixels SP can include a first subpixel SP1, a second subpixel SP2, and a third subpixel SP3, each including light-emitting areas EA for emitting light of respective colors. The first subpixel SP1 can include a first light-emitting area EA1 emitting light of a first color, the second subpixel SP2 can include a second light-emitting area EA2 emitting light of a second color, and the third subpixel SP3 can include a third light-emitting area EA3 emitting light of a third color.

The first light-emitting area EA1 can be a red light-emitting area, the second light-emitting area EA2 can be a green light-emitting area, and the third light-emitting area EA3 can be a blue light-emitting area, but are not limited thereto and other variations are possible. One first light-emitting area EA1, two second light-emitting areas EA2, and one third light-emitting area EA3 can form a single pixel in a diamond arrangement.

Conductive patterns VL1, VL2, 410, and RE can be disposed. The conductive patterns can include first conductive patterns VL1 and VL2, second conductive patterns 410, and a third conductive pattern RE. The first conductive patterns VL1 and VL2 can be data lines DL for transmitting data voltages. The second conductive patterns 410 can be a driving voltage line DVL for transmitting a high-level driving voltage. The third conductive pattern RE can be a relay electrode. These conductive patterns can be formed of the aforementioned second source-drain metal.

The first conductive patterns VL1 and VL2 and the second conductive patterns 410 can extend in a first direction and be disposed on the first planarization layer 331. The light-emitting areas EA1, EA2, and EA3 of the plurality of subpixels SP can be disposed to overlap at least one of the first conductive patterns VL1, VL2 and/or at least one of the second conductive patterns 410, but not limited thereto.

The first light-emitting area EA1 and the third light-emitting area EA3 can be disposed to overlap portions of at least one of the first conductive patterns VL1 and VL2. In other words, the openings corresponding to the first and third light-emitting areas EA1 and EA3 can be located to overlap portions of the conductive patterns VL1 and VL2, for example, the opening corresponding to the first light-emitting area EA1 can be located to overlap a portion of the conductive pattern VL1 and the opening corresponding to the first light-emitting area EA1 can be located to overlap a portion of the conductive pattern VL2, and the opening corresponding to the third light-emitting area EA3 can be located to overlap a portion of the conductive pattern VL1 and the opening corresponding to the third light-emitting area EA3 can be located to overlap a portion of the conductive pattern VL2, but not limited thereto. From the perspective of the first conductive patterns VL1 and VL2, a plurality of first conductive patterns can be disposed so as to pass underneath at least one of the first and third light-emitting areas.

The second light-emitting area EA2 can be disposed to overlap a portion of at least one of the second conductive patterns 410. In other words, the opening corresponding to the second light-emitting area EA2 can be located to overlap a portion of the second conductive patterns 410. From the perspective of the second conductive patterns 410, the second conductive patterns 410 can be disposed so as to pass beneath at least one of the second light-emitting areas EA2. The second light-emitting area EA2 may not overlap the first conductive patterns VL1 and VL2.

The second light-emitting area EA2 can be disposed in an inclined direction relative to the first direction. Specifically, the second light-emitting area EA2 can be disposed at a predetermined angle with respect to the first direction in which the plurality of first conductive patterns VL1 and VL2 and second conductive patterns 410 extend.

A plurality of the first conductive patterns VL1 and VL2 can be arranged in pairs.

For example, the first conductive pattern VL1 and the first conductive pattern VL2 can be arranged adjacent to each other as a pair. The pair of first conductive patterns VL1 and VL2 can be disposed in a region between two different second conductive patterns 410. For example, the pair of first conductive patterns VL1 and VL2 can be disposed in a region between two different second conductive patterns 410, and portions of the pair of first conductive patterns VL1 and VL2 can overlap the openings corresponding to the first and third light-emitting areas EA1 and EA3, but not limited thereto.

The first conductive pattern VL1 can supply a data voltage for image display to the first subpixel SP1. The first conductive pattern VL2 can supply a data voltage for image display to the third subpixel SP3. The first conductive pattern VL1 can supply a data voltage for image display to the second subpixel SP2.

Alternatively, the first conductive pattern VL1 can supply a data voltage for image display to the second subpixel SP2, and the first conductive pattern VL2 can supply a data voltage for image display to the first and third subpixels SP1 and SP3.

The second conductive patterns 410 can transmit a high-level driving voltage for driving the subpixels SP.

The first and third light-emitting areas EA1 and EA3 can be disposed on the first conductive patterns VL1 and VL2. The second light-emitting area EA2 can be disposed on the second conductive patterns 410. Depending on the design of the conductive patterns, the second light-emitting area EA2 can be partially overlapped with the second conductive patterns 410.

The third conductive pattern RE can be disposed to partially overlap the pixel electrode PE of the light-emitting device. The third conductive pattern RE can be the relay electrode that electrically connects the pixel electrode PE of the light-emitting device and the source/drain electrode of the transistor. A contact hole CH connecting the pixel electrode PE of the light-emitting device and the relay electrode RE can be located in a region not overlapping the light-emitting area EA.

Meanwhile, as illustrated in FIGS. 3 and 4, multiple light-emitting areas EA can be arranged in a narrow region, and various components including a plurality of wirings and driving elements for supplying signals and voltages can be formed below the light-emitting areas EA so as to overlap with the light-emitting areas EA. As these various components are formed, the surface can become non-planar due to level differences, and such unevenness can be transferred to the pixel electrode of the light-emitting device when the pixel electrode is formed. When step differences are present in the pixel electrode, the emitted light can become uneven and reflectivity can deteriorate.

To stably position the light-emitting device on a planar surface and improve the planarity of the pixel electrode, a plurality of planarization layers made of organic materials can be formed. In the process of forming such organic planarization layers, gas can be generated from the organic films, and if the gas is not sufficiently discharged, it can cause a decrease in the reliability of the display panel.

Accordingly, a solution is needed that addresses both the step differences caused by the conductive patterns disposed below the pixel electrode and the outgassing issue from multiple planarization layers.

The barrier layer 332 can be disposed to cover the entire lower region of the pixel electrode PE. The barrier layer 332 can be arranged such that portions of the top surfaces of the conductive patterns VL1, VL2, 410, and RE are exposed, for example, the barrier layer 332 can be arranged such that a portions of the top surface of each of the conductive patterns VL1, VL2, 410, and RE are exposed, thereby reducing or preventing the step difference caused by the conductive patterns.

A via hole TH can be disposed between the conductive patterns VL1, VL2, 410, and RE. The via hole TH can be disposed so as not to overlap the conductive patterns. The via hole TH can be included in the barrier layer 332 disposed on the planarization layer. By disposing the via hole TH in the barrier layer 332, gas generated from the planarization layer below the barrier layer 332 can be continuously discharged.

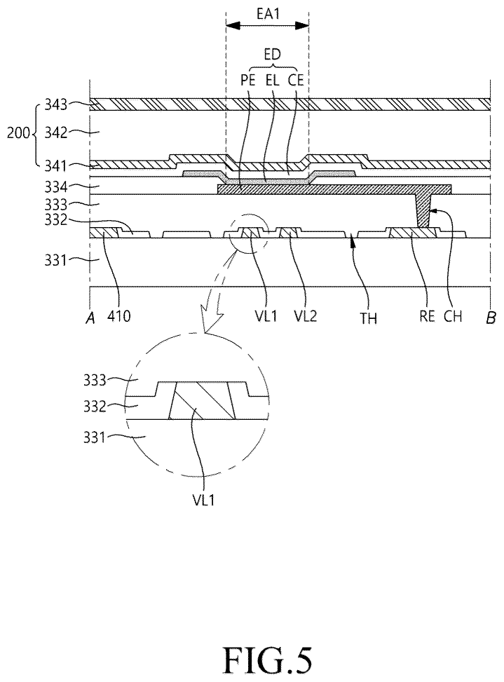

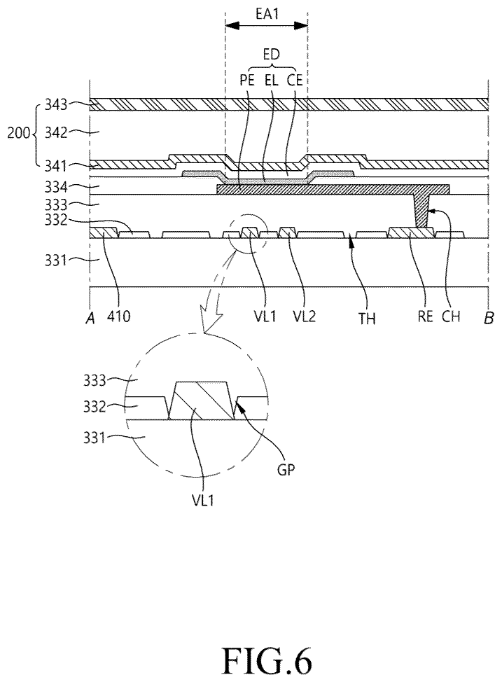

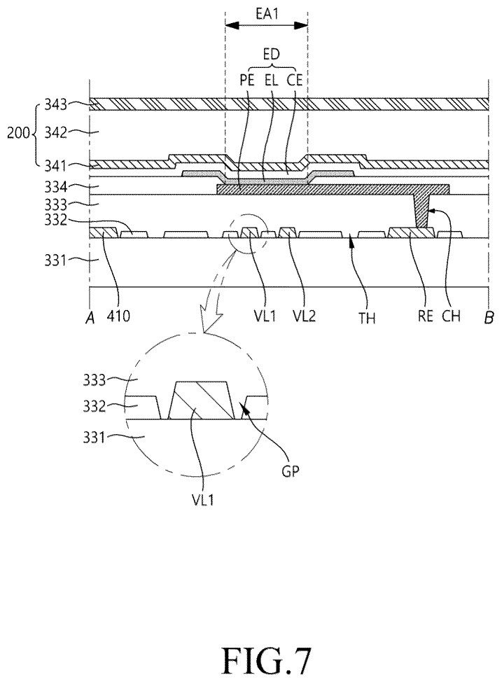

FIG. 5, FIG. 6 and FIG. 7 are different example cross-sectional views taken along line A-B of FIG. 4. In the following description, content that is the same or similar to what has already been described with reference to FIG. 1 to FIG. 4 is omitted or briefly explained.

Referring to one example of FIG. 5, the display device can include a first planarization layer 331, conductive patterns VL1, VL2, 410 and RE, a barrier layer 332, a second planarization layer 333, a light-emitting device ED, a bank 334, and an encapsulation layer 200.

The conductive patterns VL1, VL2, 410 and RE can be disposed on the first planarization layer 331 and spaced apart from each other. The conductive patterns can include first conductive patterns VL1 and VL2, a second conductive patterns 410, and a third conductive pattern RE. The first conductive patterns VL1 and VL2 can be data lines DL that deliver data voltages. The second conductive patterns 410 can be a voltage line DVL for transmitting a high-level driving voltage. The third conductive pattern RE can be a relay electrode.

The barrier layer 332 can be disposed on the first planarization layer 331. The barrier layer 332 can be disposed in regions of the first planarization layer 331 where the conductive patterns VL1, VL2, 410 and RE are not formed. The barrier layer 332 may not be disposed on at least a portion of the top surfaces of the conductive patterns, for example, the barrier layer 332 may not be disposed on at least a portion of the top surface of each of the conductive patterns VL1, VL2, 410 and RE. By being disposed between the conductive patterns VL1, VL2, 410 and RE, the barrier layer 332 can function to alleviate step differences caused by the conductive patterns.

The barrier layer 332 can include the via hole TH positioned between the conductive patterns. The via hole TH can function to discharge gas that can be generated from the first planarization layer 331 made of an organic film, i.e., for outgassing.

The second planarization layer 333 can be disposed on the conductive patterns VL1, VL2, 410 and RE and the barrier layer 332. The second planarization layer 333 can further improve surface planarity by covering the conductive patterns and the barrier layer.

The barrier layer 332 may not be disposed on portions of the top surfaces of the conductive patterns VL1, VL2, 410, and RE, for example, the barrier layer 332 may not be disposed on a portion of the top surface of each of the conductive patterns VL1, VL2, 410, and RE. For example, the barrier layer 332 can be disposed on remaining regions other than portions of the top surfaces of the conductive patterns. Alternatively, the barrier layer 332 may not be disposed on the entire top surfaces of the conductive patterns VL1, VL2, 410 and RE, for example, the barrier layer 332 may not be disposed on the entire top surface of each of the conductive patterns VL1, VL2, 410 and RE. The region not covered by the barrier layer 332 on the top surfaces of the conductive patterns VL1, VL2, 410 and RE can be referred to as an open area. For example, the open area can correspond to a portion or the entirety of the top surface of the conductive patterns VL1, VL2, 410 and RE.

The barrier layer 332 can be disposed in contact with the side surfaces of the conductive patterns VL1, VL2, 410 and RE, for example, the barrier layer 332 can be disposed in contact with the side surfaces of each of the conductive patterns VL1, VL2, 410 and RE. The barrier layer 332 can be disposed at the same or lower height compared to the top surfaces of the conductive patterns VL1, VL2, 410 and RE. The barrier layer 332 can be disposed to be in contact with side surfaces of the conductive patterns VL1, VL2, 410, and RE, and the second planarization layer 333 can be disposed to be in contact with top surfaces of the conductive patterns VL1, VL2, 410, and RE. Since the barrier layer 332 is disposed at a height equal to or lower than the conductive patterns VL1, VL2, 410, and RE, a step difference caused by the conductive patterns VL1, VL2, 410, and RE can be reduced or prevented.

The via hole TH can be formed in the barrier layer 332. At the via hole TH, the first planarization layer 331 and the second planarization layer 333 can be in contact with each other. The via hole TH can be located between the conductive patterns VL1, VL2, 410, and RE. The via hole TH can be disposed in a region overlapping with or not overlapping with the opening of the bank 334. For example, the via hole TH can be disposed in both a region overlapping with the opening of the bank 334 and a region not overlapping with the opening of the bank 334. In another example, the via hole TH can be disposed in a region overlapping with the opening of the bank 334 and may not be disposed in a region not overlapping with the opening of the bank 334. In still another example, the via hole TH can be disposed in a region not overlapping with the opening of the bank 334 and may not be disposed in a region overlapping with the opening of the bank 334.

The light-emitting device ED can be formed on the second planarization layer 333. The light-emitting device ED can include a pixel electrode PE, an intermediate layer EL, and a common electrode CE. The light-emitting area EA1 of the light-emitting device ED can be formed in a region where the pixel electrode PE, the intermediate layer EL, and the common electrode CE are stacked and in contact with each other.

The pixel electrode PE can be disposed on the second planarization layer 333.

The bank 334 can be disposed on the pixel electrode PE. An opening portion of the bank 334 can expose a portion of the pixel electrode PE to define a light-emitting area. For example, the opening can overlap a portion of the pixel electrode PE. The opening of the bank 334 can correspond to the light-emitting area EA1.

The intermediate layer EL of the light-emitting device ED can be disposed on a portion of the pixel electrode PE and the bank 334. The common electrode CE can be disposed on the intermediate layer EL.

The encapsulation layer 200 can be disposed on the common electrode CE. The encapsulation layer 200 can prevent moisture or oxygen from penetrating into the light-emitting device ED.

For example, the encapsulation layer 200 has a structure in which inorganic encapsulation layers and organic encapsulation layers are alternately stacked, such that the encapsulation layer 200 can protect the light-emitting element while inhibiting moisture or oxygen from penetrating into the light-emitting element. For example, the encapsulation layer 200 can have a multi-insulating film structure in which organic films and inorganic films are stacked alternately. The inorganic film can block permeation of moisture or oxygen. The organic film can planarize a surface of the inorganic film. When the organic film and the inorganic film are stacked in multiple layers, a movement path of moisture or oxygen can be longer than that of a single layer, thereby effectively blocking the permeation of moisture and oxygen affecting the light emitting layer. The encapsulation layer 200 can be formed by sequentially stacking a first inorganic encapsulation layer, a first organic encapsulation layer, and a second inorganic encapsulation layer. The encapsulation layer 200 can further include one or more organic encapsulation layers and/or at least one inorganic encapsulation layer.

The first inorganic encapsulation layer and the second inorganic encapsulation layer can be made of an inorganic insulating material capable of low-temperature deposition, such as silicon nitride (SiNx), silicon oxide (SiOx), silicon oxynitride (SiON), or aluminum oxide (Al2O3), but not limited thereto.

The first organic encapsulation layer can be made of an organic insulating material, such as acrylic resin, epoxy resin, polyimide, polyethylene, or silicon oxycarbon (SiOC), but not limited thereto.

Alternatively, the encapsulation layer 200 includes a first inorganic encapsulation layer, a first organic encapsulation layer, a second inorganic encapsulation layer, a second organic encapsulation layer, and a third inorganic encapsulation layer stacked sequentially. However, the present disclosure is not limited thereto.

The first inorganic encapsulation layer, the second inorganic encapsulation layer, and the third inorganic encapsulation layer can serve to block the penetration of moisture or oxygen. The first inorganic encapsulation layer, the second inorganic encapsulation layer, and the third inorganic encapsulation layer can be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer can each have a larger thickness than each of the first inorganic encapsulation layer, the second inorganic encapsulation layer, and the third inorganic encapsulation layer in order to adsorb or block particles that can be produced during a process of manufacturing the display device. The first organic encapsulation layer and the second organic encapsulation layer can fill cracks that can be formed in the first inorganic encapsulation layer and the second inorganic encapsulation layer. The first organic encapsulation layer and the second organic encapsulation layer can planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer can planarize an upper portion of the first inorganic encapsulation layer by covering particles on the first inorganic encapsulation layer. For example, the second organic encapsulation layer can planarize an upper portion of the second inorganic encapsulation layer by covering particles on the second inorganic encapsulation layer. The first organic encapsulation layer and the second organic encapsulation layer can be made of an organic material, and for example, epoxy polymer, acrylic polymer, or the like can be used. However, the present disclosure is not limited thereto.

Meanwhile, the encapsulation layer 200 is not limited to three or five layers, for example, n layers alternately stacked between inorganic encapsulation layer and organic encapsulation layer (where n is an integer greater than 3) can be included.

FIG. 6 is another example cross-sectional view taken along line A-B of FIG. 4. The cross-section shown in FIG. 6 differs from that in FIG. 5 only in the structure of the conductive patterns VL1, VL2, 410 and RE and the barrier layer 332; other configurations are substantially the same and are not redundantly described.

Referring to FIG. 6, the barrier layer 332 can be disposed in regions of the first planarization layer 331 where the conductive patterns VL1, VL2, 410, and RE are not formed. The barrier layer 332 may not be disposed on at least a portion of the top surfaces of the conductive patterns, for example, the barrier layer 332 may not be disposed on at least a portion of the top surface of each of the conductive patterns VL1, VL2, 410, and RE.

The barrier layer 332 can be disposed such that it contacts the lower side portions of the conductive patterns VL1, VL2, 410, and RE but is spaced apart from the upper side portions thereof. A gap part GP can be defined between the upper side surface of the barrier layer 332 and the upper side surface of the conductive patterns. The barrier layer 332 can be disposed at a height lower than the top surfaces of the conductive patterns. The second planarization layer 333 can be disposed so as to contact the top and side surfaces of the conductive patterns, including the gap part GP. Because the barrier layer 332 is disposed lower than the height of the conductive pattern VL1, VL2, 410, and RE s, step differences caused by the conductive patterns can be improved.

The via hole TH can be disposed in the barrier layer 332. The first planarization layer 331 and the second planarization layer 333 can come into contact with each other at the via hole TH. The via hole TH can be positioned between the conductive patterns VL1, VL2, 410, and RE. The via hole TH can be disposed in a region overlapping and/or not overlapping with the opening of the bank 334. For example, the via hole TH can be disposed in both a region overlapping with the opening of the bank 334 and a region not overlapping with the opening of the bank 334. In another example, the via hole TH can be disposed in a region overlapping with the opening of the bank 334 and may not be disposed in a region not overlapping with the opening of the bank 334. In still another example, the via hole TH can be disposed in a region not overlapping with the opening of the bank 334 and may not be disposed in a region overlapping with the opening of the bank 334.

FIG. 7 is another example cross-sectional view taken along line A-B of FIG. 4. The cross-section illustrated in FIG. 7 differs from those in FIG. 5 and FIG. 6 only in the structure of the conductive patterns VL1, VL2, 410 and RE and the barrier layer 332. Other components are substantially the same and are not redundantly described.

Referring to FIG. 7, the barrier layer 332 can be disposed in regions of the first planarization layer 331 where the conductive patterns VL1, VL2, 410, and RE are not formed. The barrier layer 332 may not be disposed on at least a portion of the top surfaces of the conductive patterns VL1, VL2, 410, and RE, for example, the barrier layer 332 may not be disposed on at least a portion of the top surface of each of the conductive patterns VL1, VL2, 410, and RE.

The barrier layer 332 can be disposed spaced apart from the conductive patterns VL1, VL2, 410, and RE. A gap part GP can be defined between the side surface of the barrier layer 332 and the side surface of the conductive patterns VL1, VL2, 410, and RE. The barrier layer 332 can be disposed at a height lower than the top surfaces of the conductive patterns VL1, VL2, 410, and RE. The second planarization layer 333 can be disposed so as to contact the top and side surfaces of the conductive patterns VL1, VL2, 410, and RE, including the gap part GP, for example, the second planarization layer 333 can be disposed so as to contact the top and side surfaces of each of the conductive patterns VL1, VL2, 410, and RE, including the gap part GP. Because the barrier layer 332 is disposed lower than the height of the conductive patterns VL1, VL2, 410, and RE, step differences caused by the conductive patterns can be improved.

The via hole TH can be disposed in the barrier layer 332. The first planarization layer 331 and the second planarization layer 333 can come into contact with each other at the via hole TH. The via hole TH can be disposed between the conductive patterns VL1, VL2, 410, and RE. The via hole TH can be positioned in a region overlapping and/or not overlapping with the opening of the bank 334. For example, the via hole TH can be disposed in both a region overlapping with the opening of the bank 334 and a region not overlapping with the opening of the bank 334. In another example, the via hole TH can be disposed in a region overlapping with the opening of the bank 334 and may not be disposed in a region not overlapping with the opening of the bank 334. In yet another example, the via hole TH can be disposed in a region not overlapping with the opening of the bank 334 and may not be disposed in a region overlapping with the opening of the bank 334.

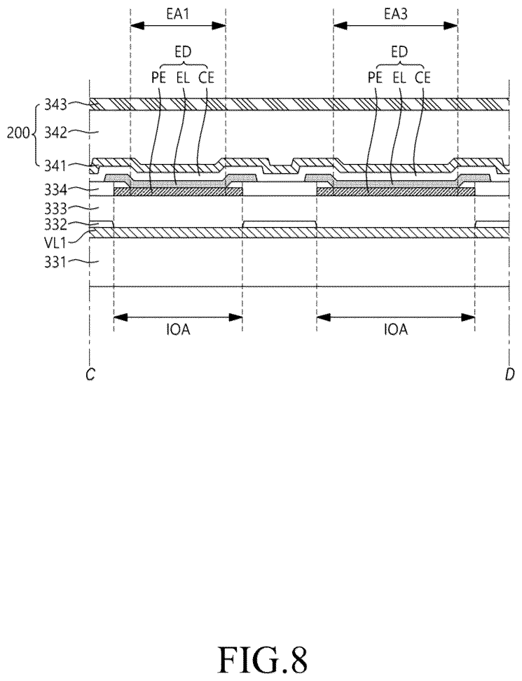

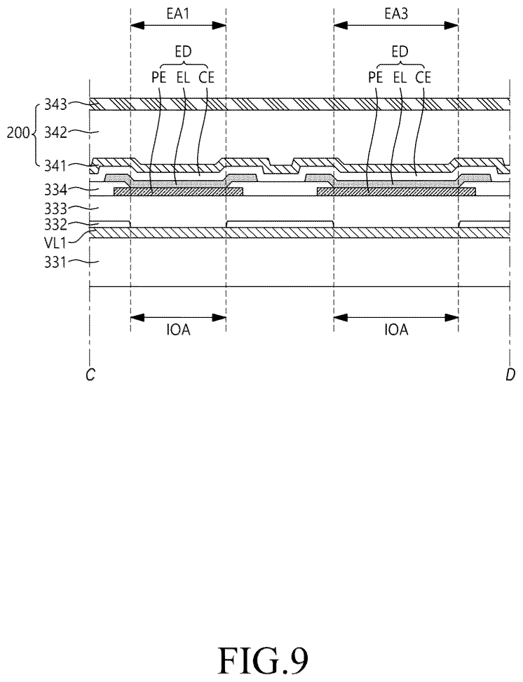

FIG. 8 and FIG. 9 are different example cross-sectional views taken along line C-D of FIG. 4. In the following description, content already described with reference to FIG. 1 to FIG. 7 is omitted or briefly described.

Referring to FIG. 8 and FIG. 9, the display device can include a first planarization layer 331, conductive patterns VL1, VL2, 410 and RE, a barrier layer 332, a second planarization layer 333, a light-emitting device ED, a bank 334, and an encapsulation layer 200.

The conductive patterns VL1, VL2, 410, and RE can be disposed on the first planarization layer 331 and spaced apart from each other. The conductive patterns can include first conductive patterns VL1 and VL2, a second conductive patterns 410, and a third conductive pattern RE. The first conductive patterns VL1 and VL2 and the second conductive patterns 410 can extend in a first direction and be spaced apart in a second direction. The first conductive patterns VL1 and VL2 can be data lines DL for transmitting data voltages, the second conductive patterns 410 can be a voltage line DVL for transmitting a high-level driving voltage, and the third conductive pattern RE can be a relay electrode.

The barrier layer 332 can be disposed on the first planarization layer 331. The barrier layer 332 can be disposed in regions of the first planarization layer 331 where the conductive patterns VL1, VL2, 410, and RE are not formed. For example, the barrier layer 332 can be located between the conductive patterns VL1, VL2, 410, and RE on the first planarization layer.

The barrier layer 332 may not be disposed on at least a portion of the top surfaces of the conductive patterns VL1, VL2, 410, and RE, for example, the barrier layer 332 may not be disposed on at least a portion of the top surface of each of the conductive patterns VL1, VL2, 410, and RE. By being positioned between the conductive patterns VL1, VL2, 410, and RE, the barrier layer 332 can improve the step differences caused by the conductive patterns VL1, VL2, 410, and RE.

The barrier layer 332 can include the via hole TH disposed between the conductive patterns VL1, VL2, 410, and RE. The via hole TH can function to discharge gas generated from the first planarization layer 331, which is an organic film, i.e., outgassing.

The second planarization layer 333 can be disposed on the conductive patterns VL1, VL2, 410, and RE and the barrier layer 332. The second planarization layer 333 can further improve flatness by covering both the conductive patterns VL1, VL2, 410, and RE and the barrier layer 332.

The light-emitting device ED can be formed on the second planarization layer 333. The light-emitting device ED can include a pixel electrode PE, an intermediate layer EL, and a common electrode CE. The light-emitting area EA1 of the light-emitting device ED can be formed in a region where the pixel electrode PE, the intermediate layer EL, and the common electrode CE are stacked and in contact.

The pixel electrode PE can be disposed on the second planarization layer 333.

The bank 334 can be disposed on the pixel electrode PE. An opening portion of the bank 334 can expose a portion of the pixel electrode PE to form a light-emitting area. For example, the opening of the bank 334 can overlap a portion of the pixel electrode. The opening of the bank can correspond to the light-emitting area EA1.

Referring to one example of FIG. 8, the barrier layer 332 may not be disposed on some portions of the top surfaces of the conductive patterns VL1, VL2, 410, and RE, for example, the barrier layer 332 may not be disposed on a portion of the top surface of each of the conductive patterns VL1, VL2, 410, and RE. For example, the barrier layer 332 may not be disposed on some regions of the top surface of the conductive patterns VL1, VL2, 410, and RE, and can be disposed on the remaining regions of the top surface of the conductive patterns VL1, VL2, 410, and RE. A region of the top surface of the conductive patterns VL1, VL2, 410, and RE on which the barrier layer 332 is not disposed can be referred to as an open area IOA. For example, the open area IOA can correspond to a portion of the top surface of the conductive patterns VL1, VL2, 410, and RE. Additionally, the open area IOA can correspond to the entire top surface of the conductive patterns VL1, VL2, 410, and RE.

The open area IOA can be disposed to overlap at least a portion of the light-emitting area EA. The open area IOA can be arranged to overlap at least a portion of the pixel electrode PE.

The open area IOA can correspond to a region where the pixel electrode PE is disposed. By providing the open area IOA, in which the barrier layer 332 is not disposed on the conductive patterns VL1, VL2, 410, and RE in the region corresponding to the pixel electrode PE, the step difference in the region where the pixel electrode PE is disposed can be improved, thereby improving the flatness of the pixel electrode PE.

In the open area IOA, the second planarization layer 333 can be disposed on the conductive patterns VL1, VL2, 410, and RE.

The intermediate layer EL of the light-emitting device ED can be disposed on a portion of the pixel electrode PE and on the bank 334. The common electrode CE can be disposed on the intermediate layer EL.

The encapsulation layer 200 can be disposed on the common electrode CE. The encapsulation layer 200 can prevent moisture or oxygen from penetrating into the light-emitting device ED.

For example, the encapsulation layer 200 has a structure in which inorganic encapsulation layers and organic encapsulation layers are alternately stacked, such that the encapsulation layer 200 can protect the light-emitting element while inhibiting moisture or oxygen from penetrating into the light-emitting element. For example, the encapsulation layer 200 can have a multi-insulating film structure in which organic films and inorganic films are stacked alternately. The inorganic film can block permeation of moisture or oxygen. The organic film can planarize a surface of the inorganic film. When the organic film and the inorganic film are stacked in multiple layers, a movement path of moisture or oxygen can be longer than that of a single layer, thereby effectively blocking the permeation of moisture and oxygen affecting the light emitting layer. The encapsulation layer 200 can be formed by sequentially stacking a first inorganic encapsulation layer, a first organic encapsulation layer, and a second inorganic encapsulation layer. The encapsulation layer 200 can further include one or more organic encapsulation layers and/or at least one inorganic encapsulation layer.

FIG. 9 is another example cross-sectional view taken along line C-D of FIG. 4 and is a different example from the view shown in FIG. 8. Compared with the cross-sectional view shown in FIG. 8, only the conductive patterns VL1, VL2, 410 and RE and the barrier layer 332 are different; other components are substantially the same, and redundant description is omitted.

Referring to FIG. 9, the barrier layer 332 may not be disposed on some portions of the top surfaces of the conductive patterns VL1, VL2, 410 and RE, for example, the barrier layer 332 may not be disposed on a portion of the top surface of each of the conductive patterns VL1, VL2, 410 and RE. For example, the barrier layer 332 can be disposed on the remaining portions of the conductive patterns VL1, VL2, 410 and RE excluding the some portions.

The open area IOA can be disposed to at least partially overlap with the light-emitting area EA. The open area IOA can also overlap at least a portion of the pixel electrode PE.

The open area IOA can correspond to the opening of the bank, which defines the light-emitting area EA. By providing an open area IOA, where the barrier layer 332 is not disposed on the conductive patterns in the region corresponding to the light-emitting area EA, step differences in the region where the light-emitting area is formed can be improved, thereby enhancing the flatness of the pixel electrode PE.

In the open area IOA, the second planarization layer 333 can be disposed on the conductive patterns VL1, VL2, 410, and RE.

Some features of the example embodiments of the present disclosure can be described as follows.

A display device according to the example embodiments of the present disclosure can include a substrate; a first planarization layer disposed on the substrate; conductive patterns disposed on the first planarization layer, adjacent conductive patterns being spaced apart from each other; a barrier layer disposed on the first planarization layer, and at least a portion of top surfaces of the conductive patterns is not covered by the barrier layer; and a second planarization layer disposed over the conductive patterns and the barrier layer.

In the display device according to the example embodiments of the present disclosure, the barrier layer can include a via hole formed between the conductive patterns. The first planarization layer and the second planarization layer can be in contact with each other at the via hole.

The display device according to the example embodiments of the present disclosure can further include a bank disposed on the second planarization layer, the bank having an opening, wherein the opening can be disposed to at least partially overlap with the conductive patterns.

In the display device according to the example embodiments of the present disclosure, the via hole may not be disposed in a region overlapping with the opening.

In the display device according to the example embodiments of the present disclosure, the opening can include a first opening and a second opening. The conductive patterns can include data lines and voltage lines. The first opening can overlap at least a portion of the data line, and the second opening can overlap at least a portion of the voltage line.

In the display device according to the example embodiments of the present disclosure, the barrier layer can be disposed in contact with side surfaces of at least a portion of the conductive patterns, and the second planarization layer can be disposed in contact with top surfaces of at least the portion of the conductive patterns.

In the display device according to the example embodiments of the present disclosure, the barrier layer can contact lower side surfaces of at least a portion of the conductive patterns and be spaced apart from upper side surfaces thereof. The second planarization layer can contact top surfaces and upper side surfaces of at least the portion of the conductive patterns.

In the display device according to the example embodiments of the present disclosure, the barrier layer can be spaced apart from at least a portion of the conductive patterns, and the second planarization layer can be disposed in contact with top and side surfaces of at least the portion of the conductive patterns.

In the display device according to the example embodiments of the present disclosure, the first and second planarization layers can include organic insulating materials, and the barrier layer can include an inorganic insulating material.

In the display device according to the example embodiments of the present disclosure, the conductive patterns can further include a relay electrode. The relay electrode can be disposed to overlap with a contact hole in the first planarization layer.

In the display device according to the example embodiments of the present disclosure, the display device can further include a transistor disposed on the substrate. The transistor can include a source electrode, a drain electrode, an active layer, and a gate electrode overlapping the active layer. The relay electrode can be electrically connected to the source electrode through the contact hole in the first planarization layer.

In the display device according to example embodiments of the present disclosure, the device can further include a light-emitting device disposed on the second planarization layer. The light-emitting device can include a pixel electrode disposed on the second planarization layer, an intermediate layer disposed on the pixel electrode, and a common electrode disposed on the intermediate layer. The pixel electrode can be electrically connected to a relay electrode through a contact hole of the second planarization layer.

In the display device according to the example embodiments of the present disclosure, the barrier layer can be disposed on the first planarization layer such that it is not disposed over the entire top surface of the conductive patterns.

In the display device according to example embodiments of the present disclosure, the conductive patterns includes first conductive patterns, a second conductive pattern, and a third conductive pattern, and wherein the first conductive patterns are data lines for transmitting data voltages, the second conductive pattern is a driving voltage line for transmitting a high-level driving voltage, and the third conductive pattern is a relay electrode.

In the display device according to example embodiments of the present disclosure, a plurality of subpixels are disposed on the substrate, the plurality of subpixels including a first subpixel, a second subpixel, and a third subpixel, wherein the first subpixel includes a first light-emitting area emitting light of a first color, the second subpixel includes a second light-emitting area emitting light of a second color, and the third subpixel includes a third light-emitting area emitting light of a third color, wherein the first light-emitting area and the third light-emitting area overlap with portions of the first conductive patterns, and wherein the second light-emitting area overlaps with a portion of the second conductive pattern.

In the display device according to example embodiments of the present disclosure, the first conductive patterns includes a pair of first conductive patterns spaced apart from each other and served as the data lines respectively.

The display device according to example embodiments of the present disclosure can include a substrate; a first planarization layer disposed on the substrate; a conductive pattern disposed on the first planarization layer and extending in a first direction; a barrier layer disposed on the first planarization layer; a second planarization layer disposed on the conductive pattern and the barrier layer; a pixel electrode disposed on the second planarization layer; and a bank disposed on the pixel electrode and including an opening that exposes a portion of the top surface of the pixel electrode. The barrier layer can include an open area not covering at least a portion of the top surface of the conductive pattern, and the open area can be disposed to overlap at least a portion of the pixel electrode.

In the display device according to the example embodiments of the present disclosure, the open area can correspond to the region of the pixel electrode.

In the display device according to the example embodiments of the present disclosure, the open area can correspond to the region of the opening.

In the display device according to the example embodiments of the present disclosure, the second planarization layer can be disposed on the conductive pattern in the open area.

In the display device according to the example embodiments of the present disclosure, the conductive pattern can be spaced apart in a second direction perpendicular to the first direction. The barrier layer can include a via hole disposed between the conductive patterns. The first and second planarization layers can be in contact with each other at the via hole.

The display device according to example embodiments of the present disclosure can include a substrate; a first planarization layer disposed on the substrate; conductive patterns disposed on the first planarization layer and extending in a first direction, adjacent conductive patterns being spaced apart in a second direction perpendicular to the first direction; a barrier layer disposed on the first planarization layer; a second planarization layer disposed on the conductive patterns and the barrier layer; and a light-emitting area overlapping the conductive patterns. The barrier layer can include an open area where it is not disposed on at least a portion of the top surfaces of the conductive patterns, and the open area can be disposed to overlap at least a portion of the light-emitting area.

In the display device according to the example embodiments of the present disclosure, the barrier layer can include a via hole disposed between the conductive patterns, and the first and second planarization layers can be in contact with each other through the via hole.

In the display device according to the example embodiments of the present disclosure, the open area can correspond to the entire top surface of the conductive patterns.

The display panel according to example embodiments of the present disclosure can include a substrate, a first planarization layer disposed on the substrate, conductive patterns positioned on the first planarization layer, adjacent conductive patterns being spaced apart from each other, a barrier layer disposed on the first planarization layer and at least a portion of top surfaces of the conductive patterns is not covered by the barrier layer, and a second planarization layer disposed on the conductive patterns and the barrier layer, wherein the barrier layer includes a via hole positioned between the conductive patterns.

The display panel according to example embodiments of the present disclosure can include a substrate, a first planarization layer disposed on the substrate, conductive patterns positioned on the first planarization layer and arranged in a first direction, a barrier layer disposed on the first planarization layer, a second planarization layer disposed on the conductive patterns and the barrier layer, a pixel electrode disposed on the second planarization layer, and a bank disposed on the pixel electrode and including an opening that exposes a portion of a top surface of the pixel electrode, wherein the barrier layer includes an open area in which at least a portion of the top surface of the conductive patterns is not covered by the barrier layer, and the open area is positioned to overlap at least a portion of the pixel electrode.

The display panel according to example embodiments of the present disclosure can include a substrate, a first planarization layer disposed on the substrate, conductive patterns positioned on the first planarization layer and extending in a first direction, adjacent conductive patterns being spaced apart in a second direction perpendicular to the first direction, a barrier layer disposed on the conductive patterns and the first planarization layer, a second planarization layer disposed on the conductive patterns and the barrier layer, and a light-emitting area disposed to overlap the conductive patterns, wherein the barrier layer includes an open area in which at least a portion of a top surface of the conductive patterns is not covered, and the open area is positioned to overlap at least a portion of the light-emitting area.

According to example embodiments of the present disclosure, the flatness of the pixel electrode can be improved by providing a barrier layer between the conductive patterns disposed under the pixel electrode.

According to example embodiments of the present disclosure, the visibility of reflected light in the display device can be enhanced by improving the flatness of the pixel electrode.

According to example embodiments of the present disclosure, outgassing from the planarization layers can be improved by providing a barrier layer having a via hole between the planarization layers.

The above description has been presented to enable any person skilled in the art to make and use the technical idea of the present disclosure, and has been provided in the context of a particular application and its requirements. Various modifications, additions and substitutions to the described example embodiments will be readily apparent to those skilled in the art, and the general principles defined herein can be applied to other example embodiments and applications without departing from the spirit and scope of the present disclosure. The above description and the accompanying drawings provide an example of the technical idea of the present disclosure for illustrative purposes only. For example, the disclosed example embodiments are intended to illustrate the scope of the technical idea of the present disclosure.

What is claimed is:

1. A display device comprising:
a substrate;
a first planarization layer disposed on the substrate;
conductive patterns disposed on the first planarization layer and being spaced apart from each other;
a barrier layer disposed on the first planarization layer, wherein at least a portion of top surfaces of the conductive patterns is not covered by the barrier layer; and
a second planarization layer disposed on the conductive patterns and the barrier layer,
wherein the barrier layer includes a via hole positioned between the conductive patterns.

2. The display device according to claim 1,
wherein the first planarization layer and the second planarization layer are in contact with each other at the via hole of the barrier layer.

3. The display device according to claim 1, further comprising a bank disposed on the second planarization layer and including an opening,
wherein the opening of the bank overlaps at least a portion of the conductive patterns.

4. The display device according to claim 3,
wherein the via hole of the barrier layer is not disposed in a region overlapping the opening of the bank.

5. The display device according to claim 3,
wherein the opening of the bank includes a first opening and a second opening,
wherein the conductive patterns include a data line configured to transmit a data voltage and a driving voltage line configured to transmit a high-level driving voltage,
wherein the first opening of the bank is disposed to overlap at least a portion of the data line, and
wherein the second opening of the bank is disposed to overlap at least a portion of the driving voltage line.

6. The display device according to claim 1,
wherein the barrier layer is disposed in contact with a side surface of at least a portion of the conductive patterns, and
wherein the second planarization layer is in contact with a top surface of at least the portion of the conductive patterns.

7. The display device according to claim 1,
wherein the barrier layer is disposed in contact with a lower side of a side surface of at least a portion of the conductive patterns and is disposed to be spaced apart from an upper side of the side surface of at least the portion of the conductive patterns, and
wherein the second planarization layer is in contact with a top surface and an upper side of a side surface of at least the portion of the conductive patterns.

8. The display device according to claim 1,
wherein the barrier layer is disposed to be spaced apart from at least a portion of the conductive patterns, and
wherein the second planarization layer is disposed in contact with a top surface and a side surface of at least the portion of the conductive patterns.

9. The display device according to claim 1,
wherein the first and second planarization layers comprise an organic insulating material, and
wherein the barrier layer comprises an inorganic insulating material.

10. The display device according to claim 5,
wherein the conductive patterns further include a relay electrode, and
wherein the relay electrode is disposed to overlap a contact hole in the first planarization layer.

11. The display device according to claim 10, further comprising a transistor disposed on the substrate,
wherein the transistor includes a source electrode, a drain electrode, an active layer, and a gate electrode disposed to overlap the active layer, and
wherein the relay electrode is electrically connected to the source electrode through the contact hole of the first planarization layer.

12. The display device according to claim 11, further comprising a light-emitting device disposed on the second planarization layer,
wherein the light-emitting device comprises:
a pixel electrode disposed on the second planarization layer;
an intermediate layer disposed on the pixel electrode; and
a common electrode disposed on the intermediate layer, and
wherein the pixel electrode is electrically connected to the relay electrode through a contact hole of the second planarization layer.

13. The display device according to claim 1, wherein the barrier layer is disposed on the first planarization layer so that the barrier layer does not cover the entire top surfaces of the conductive patterns.

14. The display device according to claim 1, wherein the conductive patterns include first conductive patterns, a second conductive pattern, and a third conductive pattern, and
wherein the first conductive patterns include data lines configured to transmit data voltages, the second conductive pattern includes a driving voltage line configured to transmit a high-level driving voltage, and the third conductive pattern includes a relay electrode.

15. A display device comprising:
a first planarization layer disposed on a substrate;
conductive patterns disposed on the first planarization layer and disposed in a first direction;
a barrier layer disposed on the first planarization layer;
a second planarization layer disposed on the conductive patterns and the barrier layer;
a pixel electrode disposed on the second planarization layer; and
a bank disposed on the pixel electrode and including an opening that exposes a portion of a top surface of the pixel electrode,
wherein the barrier layer includes an open area in which at least a portion of a top surface of the conductive patterns is not covered by the barrier layer, and
wherein the open area of the barrier layer overlaps at least a portion of the pixel electrode.

16. The display device according to claim 15,
wherein the open area of the barrier layer corresponds to the pixel electrode.

17. The display device according to claim 15,
wherein the open area of the barrier layer corresponds to the opening of the bank.

18. The display device according to claim 15,
wherein the second planarization layer is disposed on the conductive patterns at the open area of the barrier layer.

19. The display device according to claim 15,
wherein the conductive patterns that are adjacent to each other are disposed to be spaced apart in a second direction perpendicular to the first direction,
wherein the barrier layer includes a via hole positioned between the conductive patterns, and
wherein the first and second planarization layers are in contact with each other at the via hole of the barrier layer.

20. A display device comprising:
a first planarization layer disposed on a substrate;
conductive patterns positioned on the first planarization layer and extending in a first direction, and being disposed to be spaced apart in a second direction perpendicular to the first direction;
a barrier layer disposed on the first planarization layer;
a second planarization layer disposed on the conductive patterns and the barrier layer; and
a light-emitting area disposed to overlap the conductive patterns,
wherein the barrier layer includes an open area in which at least a portion of a top surface of the conductive patterns is not covered by the barrier layer, and
wherein the open area of the barrier layer overlaps at least a portion of the light-emitting area.
